(19) United States
(12) Patent Application Publication
(10) Pub. No.: US 2018/0374653 A1
(43) Pub. Date: Dec. 27, 2018

(54) PHOTOELECTRIC CONVERSION ELEMENT AND PHOTOELECTRIC CONVERSION MODULE

(71) Applicants: FUJIFILM Corporation, Tokyo (JP); SHARP KABUSHIKI KAISHA, Sakai City (JP)

(72) Inventors: Kousuke WATANABE, Ashigarakami-gun (JP); Naoyuki HANAKI, Ashigarakami-gun (JP); Kazuhiro TSUNA, Ashigarakami-gun (JP); Ryohsuke YAMANAKA, Sakai City (JP); Atsushi FUKUI, Sakai City (JP); Hisayuki UTSUMI, Sakai City (JP); Megumi KASAHARA, Sakai City (JP); Yuichi ICHINOSE, Sakai City (JP)

(73) Assignees: FUJIFILM Corporation, Tokyo (JP); SHARP KABUSHIKI KAISHA, Sakai City (JP)

(21) Appl. No.: 16/118,811

(22) Filed: Aug. 31, 2018

Related U.S. Application Data
(63) Continuation of application No. PCT/JP2017/004628, filed on Feb. 8, 2017.

(30) Foreign Application Priority Data
Mar. 4, 2016 (JP) 2016-042561

(51) Int. Cl. H01G 9/20; C07F 15/00; H01L 51/00; C09B 57/10

(52) U.S. Cl. CPC H01G 9/2059; H01G 9/2022; C09B 57/10; C07F 15/0053; H01L 51/0086; H01G 9/2081

(57) ABSTRACT

Provided is a photoelectric conversion element including a supporting substrate, a conductive layer, a power generating layer onto which a metal complex dye is adsorbed, and a counter electrode, in which the conductive layer, the power generating layer, and the counter electrode are laminated in this order on the supporting substrate, some or all of voids provided in each of the power generating layer and the counter electrode contain an electrolyte, an adsorption amount of the metal complex dye is 1.0×10⁻⁸ to 1.8×10⁻⁷ mol/cm², and the metal complex dye is represented by a specific formula. Also provided is a photoelectric conversion module including a plurality of the photoelectric conversion elements connected to each other.

### CROSS-REFERENCE TO RELATED APPLICATIONS

This application is a Continuation of PCT International Application No. PCT/JP2017/004628 filed on Feb. 8, 2017, which claims priorities under 35 U.S.C. § 119 (a) to Japanese Patent Application No. JP2016-042561 filed on Mar. 4, 2016. Each of the above applications is hereby expressly incorporated by reference, in its entirety, into the present application.

### BACKGROUND OF THE INVENTION

### 1. Field of the Invention

The present invention relates to a photoelectric conversion element and a photoelectric conversion module.

### 2. Description of the Background

Photoelectric conversion elements are used in various photosensors, copy machines, solar cells, and the like. The photoelectric conversion elements have been put to practical use in the form of photoelectric conversion elements adopting various modes, such as photoelectric conversion elements using metals, photoelectric conversion elements using semiconductors, photoelectric conversion elements using organic pigments or dyes, or photoelectric conversion elements as a combination of these. Because solar cells using inexhaustible solar energy do not require fuel and use inexhaustible clean energy, full-scale commercialization of solar cells is highly anticipated. Among solar cells, silicon-based solar cells have been researched and developed for a long period of time, and are becoming increasingly popular by the political support of each country. However, in order to greatly reduce the cost of power generation down to a level corresponding to the current grid parity, a big breakthrough needs to be achieved.

Photoelectric conversion elements in which a metal complex dye is used as a sensitizing dye can be manufactured mainly by a coating process or a printing process. Because a huge cost down is anticipated, the photoelectric conversion elements are actively researched.

U.S. Pat. No. 5,463,057A describes a dye sensitized photoelectric conversion element using semiconductor fine particles sensitized by a ruthenium metal complex dye by applying the aforementioned technique. Since then, in order to improve the photoelectric conversion efficiency, ruthenium metal complex-based sensitizing dyes have been continuously developed (see US2010/0258175A).

### SUMMARY OF THE INVENTION

Numerous research and development using N749 as a ruthenium metal complex dye having a terpyridyl-based ligand are being conducted, and the ruthenium metal complex dye described in US2010/0258175A is obtained by improving N749. However, even though these ruthenium metal complex dyes are used, the photoelectric conversion element still has problems of low photoelectric conversion efficiency and low heat-resistant durability.

The present invention has been made in consideration of the current circumstances, and an object thereof is to provide a photoelectric conversion element, which makes it possible to improve the photoelectric conversion efficiency and achieve high heat-resistant durability, and a photoelectric conversion module in which the photoelectric conversion element is used.

The aforementioned object was achieved by means described below.

[1] A photoelectric conversion element comprising a supporting substrate, a conductive layer, a power generating layer onto which a metal complex dye is adsorbed, and a counter electrode, in which the conductive layer, the power generating layer, and the electrode are laminated in this order on the supporting substrate, some or all of voids provided in each of the power generating layer and the counter electrode contain an electrolyte, an adsorption amount of the metal complex dye is 1.0×10⁻⁸ to 1.8×10⁻⁷ mol/cm², and the metal complex dye is represented by Formula (1).

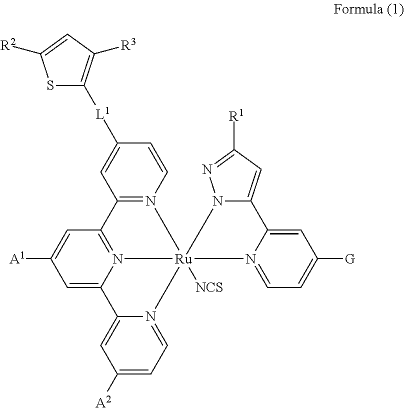

In Formula (1), G represents a group represented by any of Formulae (G-1) to (G-4). A¹ and A² each independently represent a carboxy group or a salt of a carboxy group. L¹ represents a group represented by any of Formulae (A-1) and (A-2). R¹ represents a hydrogen atom, an alkyl group, or an aryl group. R² represents a hydrogen atom or an alkyl group. R³ represents an alkyl group.

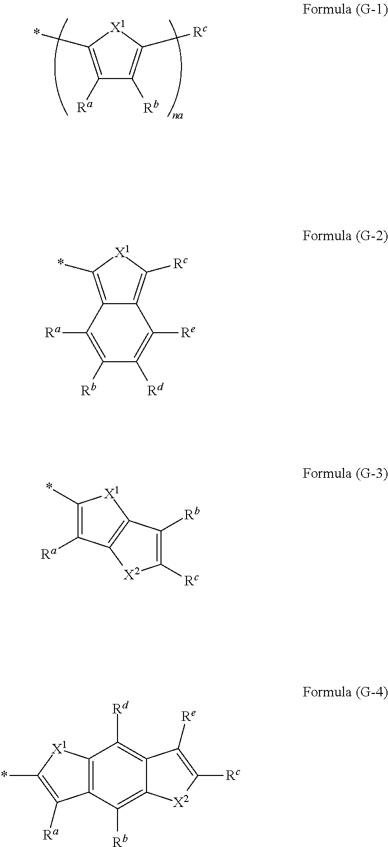

In Formulae (G-1) to (G-4), X¹ and X² each independently represent —O—, —S—, —Se—, —N(R^{A})—, —C(R^{A})₂—, or —Si(R^{A})₂—. R^{A} represents a hydrogen atom, an alkyl group, or an aryl group. na is an integer of 1 to 3. R^{a} represents an alkyl group, an alkoxy group, an alkylthio group, or an amino group. R^{b}, R^{c}, R^{d}, and R^{e} each independently represent a hydrogen atom or a substituent. * represents a position bonded to a pyridyl group.

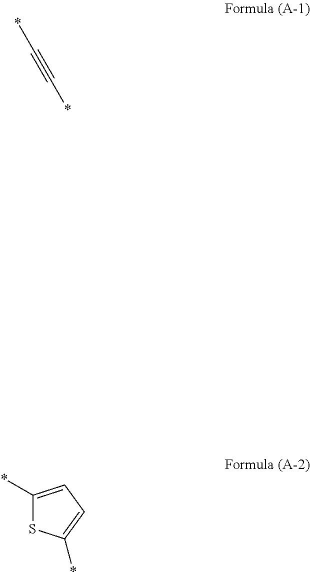

In each of Formulae (A-1) and (A-2), one of two *'s represents a position bonded to a thienyl group, and the other represents a position bonded to a pyridyl group.

[2] The photoelectric conversion element described in [1], in which G is represented by Formula (G-1).

[3] The photoelectric conversion element described in [1] or [2], in which the metal complex dye is represented by Formula (2).

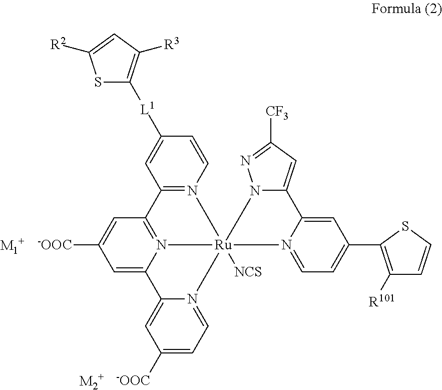

In Formula (2), M₁⁺ and M₂⁺ each independently represent a proton or a counterion. L¹ represents a group represented by any of Formulae (A-1) and (A-2). R¹⁰¹ represents an alkyl group. R² represents a hydrogen atom or an alkyl group. R³ represents an alkyl group.

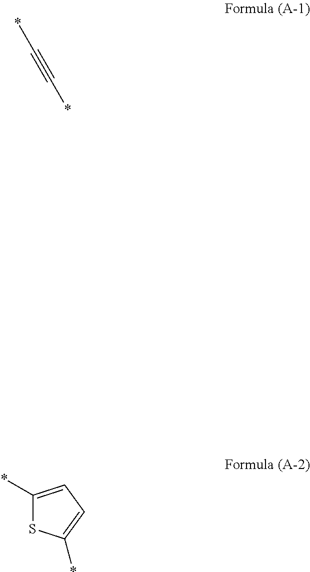

In each of Formulae (A-1) and (A-2), one of two *'s represents a position bonded to a thienyl group, and the other represents a position bonded to a pyridyl group.

[4] The photoelectric conversion element described in [3], in which R¹⁰¹ represents an alkyl group having 2 to 12 carbon atoms.

[5] The photoelectric conversion element described in any one of [1] to [4], in which the power generating layer includes a porous semiconductor layer.

[6] The photoelectric conversion element described in any one of [1] to [5], in which the power generating layer includes a laminate of the porous semiconductor layer and a porous insulating layer.

[7] The photoelectric conversion element described in [6], in which a film thickness of the porous insulating layer is 3 to 12 μm.

[8] The photoelectric conversion element described in [6] or [7], in which the porous insulating layer is formed of at least one kind of insulating material selected from the group consisting of zirconium oxide, silicon oxide, aluminum oxide, magnesium oxide, and titanium oxide.

[9] The photoelectric conversion element described in [8], in which an average particle size of the zirconium oxide, the silicon oxide, the aluminum oxide, and the magnesium oxide is 50 to 300 nm, and an average particle size of the titanium oxide is 100 to 600 nm.

[10] The photoelectric conversion element described in any one of [5] to [9], in which the porous semiconductor layer is formed of a semiconductor material having an average particle size of 5 to 50 nm.

[11] The photoelectric conversion element described in any one of [1] to [10], in which the counter electrode includes a catalyst layer and a conductive layer.

[12] The photoelectric conversion element described in [11], in which the conductive layer included in the counter electrode contains at least one kind of material among titanium, molybdenum, nickel, and carbon.

[13] A photoelectric conversion module comprising a plurality of the photoelectric conversion elements described in any one of [1] to [12] that are connected to each other in series.

In the present specification, unless otherwise specified, regarding a carbon-carbon double bond, in a case where an E-isomer and a Z-isomer are present in a molecule, the molecule may be either the E-isomer or the Z-isomer or may be a mixture of these. Furthermore, in a case where there are a plurality of substituents, linking groups, ligands, and the like (hereinafter, referred to as substituents and the like) marked with a specific reference, or in a case where the plurality of substituents and the like are specified collectively or selectively, unless otherwise specified, the substituents and the like may be the same as or different from each other. The same will be applied to a case where the number of substituents and the like is specified. In addition, in a case where the plurality of substituents and the like are close to each other (particularly, in a case where the substituents and the like are adjacent to each other), unless otherwise specified, the substituents and the like may form a ring by being linked to each other. Moreover, rings, for example, an alicyclic ring, an aromatic ring, or a heterocyclic ring may form a fused ring by being further fused.

The present invention can provide a photoelectric conversion element, which improves the photoelectric conversion efficiency and exhibits high heat-resistant durability, and a photoelectric conversion module in which the photoelectric conversion element is used.

The aforementioned characteristics as well as other characteristics and advantages of the present invention will be further clarified by the following description with reference to the attached drawing as appropriate.

### BRIEF DESCRIPTION OF THE DRAWINGS

FIG. 1 is a cross-sectional view schematically showing an enlarged photoelectric conversion element in a preferred aspect of a photoelectric conversion module of the present invention.

FIG. 2 is a cross-sectional view schematically showing a preferred aspect of the photoelectric conversion module of the present invention.

FIG. 3 shows the ¹H-NMR spectrum of a compound (3-7) which is a synthesis intermediate in a synthesis example of a metal complex dye Dye51.

FIG. 4 shows the ¹H-NMR spectrum of a metal complex dye Dye52.

### DESCRIPTION OF THE PREFERRED EMBODIMENTS

Hereinafter, an embodiment of the present invention will be specifically described. The embodiment is merely an example, and the present invention can be embodied in various aspects within the scope of the present invention.

In the present specification, a range of numerical values described using “to” means a range including the numerical values listed before and after “to” as a lower limit and an upper limit respectively.

<<Photoelectric Conversion Module>>

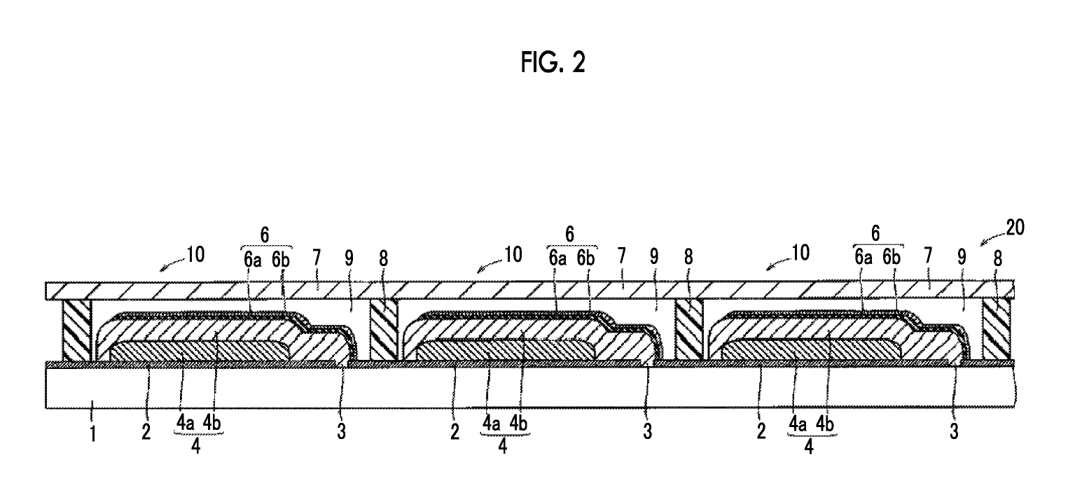

The photoelectric conversion module (dye sensitized solar cell) of the present invention is not particularly limited as long as the module is obtained by connecting a plurality of photoelectric conversion elements of the present invention as shown in FIG. 2, for example. The photoelectric conversion element included in the photoelectric conversion module of the present invention may include the photoelectric conversion element of the present invention or a photoelectric conversion element other than the photoelectric conversion element of the present invention.

In the photoelectric conversion module, the number of photoelectric conversion elements connected to each other is not particularly limited, and can be appropriately set according to the use, performance, and the like. FIG. 2 shows a portion of a photoelectric conversion module 20 in which a number of photoelectric conversion elements 10 are connected to each other (a portion where three photoelectric conversion elements 10 are connected to each other on one end side).

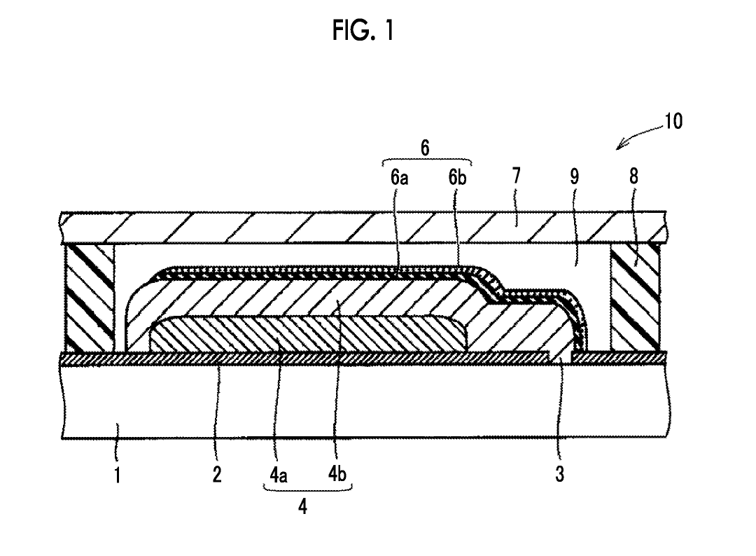

The method for connecting the photoelectric conversion elements is not particularly limited, and is appropriately determined. For example, a method can be used in which for the photoelectric conversion elements 10 shown in FIG. 1 that are adjacent to each other and separated by a scribe line 3, a conductive layer 2 of one photoelectric conversion element 10 (right side in FIG. 2) is electrically connected to a counter electrode 6 of the other photoelectric conversion element 10 (left side in FIG. 2) (serial connection) as shown in FIG. 2. Furthermore, a method can also be used in which for two photoelectric conversion elements adjacent to each other and separated by a scribe line, a counter electrode of one photoelectric conversion element is allowed to extend to protrude from a sealing material and electrically connected to a conductive layer of the other photoelectric conversion element (serial connection), although this method is not shown in the drawing.

<<Photoelectric Conversion Element>>

The photoelectric conversion element of the present invention may have a conductive layer, a power generating layer, and a counter electrode in this order on a supporting substrate, and other constitutions can be appropriately set.

As a preferred aspect of the photoelectric conversion element of the present invention, the photoelectric conversion element 10 shown in FIG. 1 can be exemplified. The photoelectric conversion element 10 has a supporting substrate 1 and a conductive layer 2, a power generating layer 4 onto which a metal complex dye (hereinafter, simply referred to as a dye in some cases) represented by Formula (1) is adsorbed, and a counter electrode (counter electrode conductive layer) 6 which are laminated in this order on the supporting substrate 1. Some or all of voids provided in each of the power generating layer 4 and the counter electrode 6 contain an electrolyte.

In the present invention, “some of voids” cannot be generally determined, but may be approximately the number of voids, which enable the photoelectric conversion element or the photoelectric conversion module to perform functions as intended or to exhibit the characteristics, among all the voids provided in each of the power generating layer 4 and the counter electrode 6. For example, as will be described later, “some of voids” can be the amount of voids that are filled by the injection of an electrolyte into the electrolyte filling region 9.

<Supporting Substrate>

Within the supporting substrate 1 in FIG. 1, a portion that will become a light receiving surface of the photoelectric conversion module needs to have light-transmitting properties. Therefore, the supporting substrate 1 is preferably formed of at least a light-transmitting material and has a thickness of about 0.2 to 5 mm.

The material constituting the supporting substrate is not particularly limited as long as the material can be generally used in a photoelectric conversion element and can exhibit the effects of the present invention. Examples of such a material include a glass substrate such as soda-lime glass, molten quartz glass, crystalline quartz glass, and borosilicate glass, heat-resistant resin substrate such as a flexible film, and the like.

Examples of materials constituting the flexible film (hereinafter, referred to as “film” as well) include triacetyl cellulose (TAC), polyethylene terephthalate (PET), polyphenylene sulfide (PPS), polycarbonate (PC), polyarylate (PA), polyetherimide (PEI), a phenoxy resin, Teflon (registered trademark), and the like.

In a case where other layers are formed on the supporting substrate by performing heating, for example, in a case where a conductive layer is formed on the supporting substrate 1 by performing heating at a temperature of about 250° C., among the aforementioned film materials, Teflon (registered trademark) that resists heat up to a temperature of equal to or higher than 250° C. is particularly preferable.

In a case where the completed photoelectric conversion element is mounted on other structures, the supporting substrate can be used. That is, by using a metal-processed part and a screw, the peripheral portion of the supporting substrate such as a glass substrate can be easily mounted on other supporting substrates.

<(First) Conductive Layer>

In FIG. 1, the conductive layer (hereinafter, referred to as a first conductive layer in some cases) 2 becomes a light receiving surface of the photoelectric conversion element and is formed of a light-transmitting material because the conductive layer 2 needs to have light-transmitting properties. Here, the conductive layer 2 may be formed of a material substantially transmitting the light of a wavelength that exhibits effective sensitivity with respect to at least a metal complex dye represented by Formula (1) which will be described later, and does not need to exhibit transmitting properties with respect to light of all the wavelength ranges.

The light-transmitting material is not particularly limited as long as the material can be generally used in photoelectric conversion elements and can exhibit the effects of the present invention. Examples of such a material include indium-tin composite oxide (ITO), fluorine-doped tin oxide (FTO), zinc oxide (ZnO), and the like.

The film thickness of the first conductive layer is preferably about 0.02 to 5 μm. The lower the film resistance of the first conductive layer, the better. The film resistance of the first conductive layer is preferably equal to or lower than 40 Ω/sq.

The first conductive layer 2 may be provided with a metal lead wire such that the resistance thereof is reduced. Examples of materials of the metal lead wire include platinum, gold, silver, copper, aluminum, nickel, titanium, and the like.

In a case where the provision of the metal lead wire results in the reduction in the amount of incidence rays from the light receiving surface, it is preferable to render the thickness of the metal lead wire become about 0.1 to 4 mm.

The first conductive layer 2 includes a scribe line 3 formed by cutting by means of laser scribing.

<Power Generating Layer>

The power generating layer 4 preferably includes a porous semiconductor layer, and more preferably includes a laminate of a porous semiconductor layer and a porous insulating layer in view of the adsorption amount of a metal complex dye and the like.

In a case where the power generating layer 4 is constituted only with a porous semiconductor layer, a metal complex dye represented by Formula (1) is adsorbed onto the porous semiconductor layer, and some or all of holes (voids) that the porous semiconductor layer has are filled with (contain) an electrolyte material.

Meanwhile, in a case where the power generating layer 4 is constituted with a laminate of a porous semiconductor layer 4a and a porous insulating layer 4b, a metal complex dye represented by Formula (1) is adsorbed onto the power generating layer 4, and some or all of holes provided in each of the porous semiconductor layer 4a and the porous insulating layer 4b are filled with an electrolyte material. The metal complex dye is adsorbed mainly onto the porous semiconductor layer 4a, but is also adsorbed onto the porous insulating layer 4b. Because the metal complex dye is adsorbed onto the porous insulating layer 4b, the amount of the dye adsorbed onto the porous semiconductor layer 4a is controlled. In addition, the metal complex dye adsorbed onto the porous insulating layer 4b functions as a filter by reducing the practical size of pores, and hence the amount of the dye adsorbed onto the porous semiconductor layer 4a is controlled.

—Porous Semiconductor Layer—

The porous semiconductor layer is constituted with a semiconductor, and it is possible to use porous semiconductor layers of various shapes such as a particle shape and a film shape having many micropores. The porous semiconductor layer preferably has a film shape having many micropores.

The semiconductor material constituting the porous semiconductor layer is not particularly limited as long as the material is generally used in photoelectric conversion elements. Examples of such a material include compounds, such as titanium oxide, zinc oxide, tin oxide, iron oxide, niobium oxide, cerium oxide, tungsten oxide, nickel oxide, strontium titanate, cadmium sulfide, lead sulfide, zinc sulfide, indium phosphide, copper-indium sulfide (CuInS₂), CuAlO₂, and SrCu₂O₂, and a combination of these. Among these, titanium oxide, zinc oxide, tin oxide, and niobium oxide are preferable, and from the viewpoint of photoelectric conversion efficiency, stability, and safety, titanium oxide is particularly preferable. Furthermore, these semiconductor materials can be used as a mixture of two or more kinds thereof.

Herein, titanium oxide includes various titanium oxides of a narrow sense such as anatase-type titanium oxide, rutile-type titanium oxide, amorphous titanium oxide, metatitanic acid, and orthotitanic acid, titanium hydroxide, hydrous titanium oxide, and the like. These can be used singly or as a mixture. The crystal system of two kinds of titanium oxides of the anatase type and the rutile type can become any form according to the preparation process or the heat history thereof, but is generally the anatase type.

From the viewpoint of stability, ease of crystal growth, manufacturing costs, and the like, the above semiconductor constituting the porous semiconductor layer is preferably a polycrystalline sintered material formed of fine particles.

From the viewpoint of obtaining a sufficiently large effective surface area with respect to a projected area such that the incidence rays are converted into electric energy at a high yield, the average particle size (simply referred to as a particle size as well) of the aforementioned fine particles is preferably equal to or greater than 5 nm and less than 50 nm, and more preferably equal to or greater than 10 nm and equal to or smaller than 30 nm.

The average particle size can be appropriately set within a predetermined range according to the conditions of the particle manufacturing method, the grinding conditions (coarse grinding, fine grinding, and final grinding), and the like. The same is true for other particles (materials). The method for measuring the average particle size will be described later.

The light-scattering properties of the porous semiconductor layer can be adjusted by the average particle size of the semiconductor material used for forming the layer. Specifically, a porous semiconductor layer formed of semiconductor particles (fine particles of a semiconductor) having a large average particle size excellently scatters light and can improve a light collecting rate by scattering the incidence rays, although these properties also depend on the formation condition of the porous semiconductor layer. Furthermore, a porous semiconductor layer formed of semiconductor particles having a small average particle size poorly scatters light but can increase an adsorption amount by further increasing the number of adsorption spots of a dye.

In addition, a layer formed of semiconductor particles having an average particle size which is equal to or greater than 50 nm and preferably equal to or greater than 50 nm and equal to or smaller than 600 nm may be provided on the polycrystalline sintered material formed of the aforementioned fine particles.

The average particle size of the semiconductor material is not particularly limited as long as the average particle size is within the aforementioned range in which the effects of the present invention can be exhibited. In view of effectively using the incidence rays for photoelectric conversion, it is preferable that the average particle size is controlled to some extent similarly to a commercially available semiconductor material powder.

The film thickness of the porous semiconductor layer is not particularly limited, but is preferably equal to or greater than 0.1 μm and more preferably about 0.5 to 50 μm in general from the viewpoint of photoelectric conversion efficiency. Particularly, in a case where a layer is provided which excellently scatters light and is formed of semiconductor particles having an average particle size of equal to or greater than 50 nm, the film thickness of the layer is preferably 0.1 to 40 μm and more preferably 5 to 20 μm. The film thickness of a layer formed of particles having an average particle size of equal to or greater than 5 nm and less than 50 nm is preferably 0.1 to 50 μm and more preferably 10 to 40 μm. The method for measuring the film thickness will be described later.

In order to improve the photoelectric conversion efficiency of the photoelectric conversion element, the power generating layer needs to be formed by causing the metal complex dye represented by Formula (1) to be adsorbed onto the porous semiconductor layer. Accordingly, it is preferable that the film-like porous semiconductor layer has an effective surface area which is preferably about 10 to 200 m²/g.

—Porous Insulating Layer—

It is preferable to provide the porous insulating layer 4b between the power generating layer 4 (porous semiconductor layer 4a) and the counter electrode 6.

As an insulating material used in the porous insulating layer, glass or the materials having a high conduction band level such as zirconium oxide, silicon oxide, aluminum oxide, niobium oxide, and strontium titanate are used. In addition, magnesium oxide and titanium oxide are also used. Among these, at least one kind of material selected from the group consisting of zirconium oxide, silicon oxide, aluminum oxide, magnesium oxide, and titanium oxide is preferable.

The porous insulating material has an effect of inhibiting the adsorption of a dye onto the power generating layer, and controls the dye adsorption amount. Therefore, in a case where the average particle size (simply referred to as a particle size as well) of the porous insulating layer (insulating material) is set according to the insulating material, the effect is more strongly exhibited.

That is, in a case where the zirconium oxide, silicon oxide, aluminum oxide, and magnesium oxide are used as insulating materials, by setting the average particle size thereof to be 50 to 300 nm, the dye adsorption inhibition effect is more strongly exhibited. In a case where the particle size is smaller than 50 nm, a carrier transport ability in an electrolytic solution deteriorates, and in a case where the particle size is larger than 300 nm, the effect of controlling the dye adsorption amount cannot be exhibited. Therefore, the average particle size is more preferably 70 to 200 nm.

In a case where titanium oxide is used as an insulating material, by setting the average particle size thereof to be 100 to 600 nm, the dye adsorption inhibition effect is more strongly exhibited. Therefore, the average particle size of the titanium oxide is more preferably 120 to 450 nm.

In order for the aforementioned effect to be more strongly exhibited, the film thickness of the porous insulating layer is preferably 3 to 12 μm. In a case where the film thickness is smaller than 3 μm, an electric insulation function is not exhibited, and the effect of controlling the dye adsorption amount is not obtained in some cases. In a case where the film thickness is larger than 12 μm, a sufficient amount of dye enough for absorbing light cannot be adsorbed onto the porous insulating layer, the resistance against carrier transport increases, and the performance deteriorates in some cases. Therefore, the film thickness of the porous insulating layer is more preferably 5 to 10 μm.

<Counter Electrode (Counter Electrode Conductive Layer) 6>

In the photoelectric conversion element 10, the counter electrode 6 is preferably constituted with a catalyst layer 6a and a conductive layer (second conductive layer) 6b. In a case where the second conductive layer 6b has a catalytic ability, the catalyst layer 6a may not be provided. Some or all of voids in the counter electrode 6 are filled with an electrolyte which will be described later.

The material constituting the second conductive layer 6b is not particularly limited as long as the material can be generally used in photoelectric conversion elements and exhibits corrosion resistance against an electrolytic solution. Examples of such a material include titanium, nickel, molybdenum, carbon, and the like. The carbon will be specifically described later. Among these, titanium is the most preferable.

In a case where the counter electrode is formed by a vapor deposition method or a sputtering method, because the film itself is porous, it is not necessary to additionally form holes through which a solution for dye adsorption or an electrolyte material moves. Here, in a case where the counter electrode has a large film thickness, the pores tend to become small. Furthermore, in a case where the film thickness of counter electrode is too small, the resistance increases, and in a case where the film thickness of the counter electrode is too large, the movement of the solution for dye adsorption or the electrolyte material is hindered.

In a case where the movement of the solution for dye adsorption or the electrolyte material is difficult, holes or grooves may be formed in the counter electrode conductive layer by laser processing or pattern formation.

The holes in the counter electrode 6 can be formed by causing the counter electrode 6 to partially evaporate by being irradiated with laser beams. The holes are preferably formed at a diameter of 0.1 to 100 μm and an interval of 1 to 200 μm, and more preferably formed at a diameter of 1 to 100 μm and an interval of 5 to 200 μm.

The optimal film thickness of the counter electrode 6 varies with specific resistance of the material, but is preferably 400 nm to 100 μm. In a case where the optimal film thickness is less than 400 nm, the value of resistance is high, and hence the output is reduced. In a case where the optimal film thickness is larger than 100 μm, the film thickness is not preferable because a problem of film peeling occurs.

If necessary, the first conductive layer 2 and the counter electrode 6 are provided with an extraction electrode (not shown in FIG. 1). The material constituting the extraction electrode is not particularly limited as long as the material can be generally used in photoelectric conversion elements and can exhibit the effects of the present invention.

—Catalyst Layer—

There is no problem in a case where the counter electrode 6 has a catalytic ability. However, in a case where the counter electrode 6 does not have a catalytic ability, it is preferable to provide a catalyst layer constituting any of the surfaces of the counter electrode. In the photoelectric conversion element 10, a catalyst layer 6a is provided between the power generating layer 4 and the second conductive layer 6b. The material constituting the catalyst layer is not particularly limited as long as the material can be generally used in photoelectric conversion elements and can exhibit the effects of the present invention. As such a material, for example, platinum and carbon are preferable. The carbon is preferably in the form of carbon black, graphite, glass carbon, amorphous carbon, hard carbon, soft carbon, a carbon whisker, a carbon nanotube, fullerene, and the like.

The catalyst layer may be formed by a vapor deposition method, a sputtering method, or a coating method using a fine particle dispersion paste of a catalyst material.

<Electrolyte>

In the photoelectric conversion element 10, an electrolyte fills an electrolyte filling region 9 surrounded by the first conductive layer 2 as well as a cover layer 7 and a sealing material 8 which will be described later, and fills some or all of the voids provided in each of the power generating layer 4 and the counter electrode 6. The electrolyte is constituted with a conductive material which can transport ions. Examples of suitable materials of the electrolyte include a liquid electrolyte, a solid electrolyte, a gel electrolyte, a molten salt gel electrolyte, and the like.

The liquid electrolyte may be a liquid material containing a redox species, and is not particularly limited as long as the liquid electrolyte can be generally used in batteries, photoelectric conversion elements, and the like. Specifically, examples thereof include a liquid electrolyte formed of a redox species and a solvent which can dissolve the redox species, a liquid electrolyte formed of a redox species and a molten salt which can dissolve the redox species, and a liquid electrolyte formed of a redox species as well as a solvent and a molten salt which can dissolve the redox species.

Examples of the redox species include redox species based on I⁻/I³⁻, Br²⁻/Br³⁻, Fe²⁺/Fe³⁺ quinone/hydroquinone, and the like. Particularly, it is preferable that the liquid electrolyte contains at least one of an iodide ion or a triiodide ion as the redox species.

Specifically, a combination of a metal iodide and iodine (I₂) such as lithium iodide (LiI), sodium iodide (NaI), potassium iodide (KI), or calcium iodide (CaI₂), a combination of a tetraalkylammonium salt and iodine such as tetraethylammonium iodide (TEAI), tetrapropylammonium iodide (TPAI), tetrabutylammonium iodide (TBAI), or tetrahexylammonium iodide (THAI), and a combination of a metal bromide and bromine such as lithium bromide (LiBr), sodium bromide (NaBr), potassium bromide (KBr), or calcium bromide (CaBr₂) are preferable. Among these, a combination of LiI and I₂ is particularly preferable.

Examples of the solvent of the redox species include a carbonate compound such as propylene carbonate, a nitrile compound such as acetonitrile, alcohols such as ethanol, water, an aprotic polar substance, and the like. Among these, a carbonate compound or a nitrile compound is particularly preferable. Two or more kinds of these solvents can be used by being mixed together.

The solid electrolyte is a conductive material which can transport electrons, holes, and ions, and may be a substance which can be used as an electrolyte for a photoelectric conversion element and does not have fluidity. Specifically, examples thereof include a hole transport material such as polycarbazole, an electron transport material such as tetranitrofluorenone, a conductive polymer such as polypyrrole, a polymer electrolyte obtained by solidifying a liquid electrolyte by using a polymer compound, a p-type semiconductor such as copper iodide or copper thiocyanate, an electrolyte obtained by solidifying a molten salt-containing liquid electrolyte by using fine particles, and the like.

The gel electrolyte is generally formed of an electrolyte (redox species) and a gelatinization agent. Examples of the gelatinization agent include a polymer gelatinization agent such as a cross-linked polyacrylic resin derivative, a cross-linked polyacrylonitrile derivative, a polyalkylene oxide derivative, silicone resins, or a polymer having a nitrogen-containing heterocyclic quaternary compound salt structure on a side chain, and the like.

The molten salt gel electrolyte is generally formed of the aforementioned gel electrolyte and a room temperature-type molten salt. Examples of the room temperature-type molten salt include a nitrogen-containing heterocyclic quaternary ammonium salt compounds such as pyridinium salts and imidazolium salts, and the like.

If necessary, additives may be added to the aforementioned electrolyte. Examples of the additives include a nitrogen-containing aromatic compound such as t-butylpyridine (TBP) and imidazole salts such as dimethylpropylimidazole iodide (DMPII), methylpropylimidazole iodide (MPII), ethylmethylimidazole iodide (EMII), ethylimidazole iodide (EII), and hexylmethylimidazole iodide (HMII).

The electrolyte concentration in the electrolyte is preferably within a range of 0.001 to 1.5 mol/L, and particularly preferably within a range of 0.01 to 0.7 mol/L. Here, in a case where the catalyst layer is on the light receiving surface side within the photoelectric conversion element of the present invention, through the electrolyte, the incidence rays reach the power generating layer onto which a dye is adsorbed, and hence carriers are excited. Accordingly, the performance deteriorates in some cases due to the concentration of the electrolyte used in the photoelectric conversion element in which the catalyst layer is on the light receiving surface side. Therefore, it is preferable to set the electrolyte concentration in consideration of such cases.

<Cover Layer>

In FIG. 1, the cover layer 7 is provided in the photoelectric conversion element 10. It is preferable that the cover layer 7 is provided for preventing the volatilization of the electrolyte and preventing water or the like from permeating the photoelectric conversion element 10.

The material constituting the cover layer 7 is not particularly limited as long as the material can be generally used in photoelectric conversion elements and can exhibit the effects of the present invention. Examples of such a material include soda lime glass, lead glass, borosilicate glass, molten quartz glass, crystalline quartz glass, and the like. As the material, soda lime float glass is particularly preferable.

<Sealing material>

In FIG. 1, the sealing material 8 is provided in the photoelectric conversion element 10. It is preferable that the sealing material is provided for preventing the volatilization of the electrolyte and preventing water or the like from permeating the photoelectric conversion element 10.

Furthermore, it is preferable that the sealing material 8 is provided for (1) absorbing a falling object or stress (impact) acting on the supporting substrate and/or for (2) absorbing flexure or the like acting on the supporting substrate during long-term use.

The material constituting the sealing material 8 is not particularly limited as long as the material can be generally used in photoelectric conversion elements and can exhibit the effects of the present invention. As such a material, for example, a silicone resin, an epoxy resin, a polyisobutylene-based resin, a hot melt resin, glass frit, and the like are preferable. Two or more kinds of these materials can be used in the form of two or more layers. In a case where a nitrile compound or a carbonate compound is used as a solvent for the electrolyte, a silicone resin, a hot melt resin (for example, an ionomer resin), a polyisobutylene-based resin, and glass frit are particularly preferable.

<<Method for Manufacturing Photoelectric Conversion Element>>

The method for manufacturing the photoelectric conversion element of the present invention is not particularly limited. The method for manufacturing the photoelectric conversion element 10 shown in FIG. 1 includes, for example, a step of forming a laminate in which the first conductive layer 2, the power generating layer 4 onto which a metal complex dye represented by Formula (1) is adsorbed, and the counter electrode 6 are laminated in this order on one surface of the supporting substrate 1, a step of forming the cover layer 7 and the sealing material 8 on the outer periphery of the laminate, and a step of injecting an electrolyte into the electrolyte filling region 9 surrounded by the first conductive layer 2, the cover layer 7, and the sealing material 8.

<Formation of First Conductive Layer>

The method for forming the first conductive layer 2 on the supporting substrate 1 is not particularly limited, and examples thereof include a known sputtering method, spray method, or the like.

In a case where a metal lead wire is provided on the first conductive layer 2, for example, it is possible to use a method of forming a metal lead wire on the supporting substrate 1 by a known sputtering method, vapor deposition method, or the like and then forming the first conductive layer 2 on the obtained supporting substrate 1 including the metal lead wire, a method of forming the first conductive layer 2 on the supporting substrate 1 and then forming a metal lead wire on the first conductive layer 2, and the like.

The scribe line 3 can be formed by cutting the first conductive layer 2 by means of laser scribing.

<Formation of Power Generating Layer>

—Formation of Porous Semiconductor Layer—

The method for forming a film-like porous semiconductor layer on the first conductive layer 2 is not particularly limited, and examples thereof include known methods. Specific examples thereof include (1) method of coating the first conductive layer with a paste containing semiconductor particles by a screen printing method, an ink jet method, or the like and then performing calcination, (2) method of forming a film on the first conductive layer by using a chemical vapor deposition (CVD) method, a metalorganic chemical vapor deposition (MOCVD) method, or the like using a desired raw material gas (3) method of forming a film on the first conductive layer by a physical vapor deposition (PVD) method, a vapor deposition method, a sputtering method, or the like using a raw material solid, (4) method of forming a film on the first conductive layer by a sol-gel method or a method using an electrochemical redox reaction, and the like. Among these, a screen printing method using a paste is particularly preferable because this method makes it possible to form a porous semiconductor layer having a large film thickness at low costs.

An example of the method for forming a porous semiconductor layer by using titanium oxide as semiconductor particles is as described below, but the present invention is not limited thereto.

First, 125 mL of titanium isopropoxide (manufactured by Kishida Chemical Co., Ltd.) is added dropwise to 750 mL of 0.1 M (mol/L) aqueous nitric acid solution (manufactured by Kishida Chemical Co., Ltd.) such that hydrolysis occurs, and heating the solution for 8 hours at 80° C., thereby preparing a sol liquid. Then, the obtained sol liquid is heated for 11 hours at 230° C. in an autoclave made of titanium such that titanium oxide particles grow, followed by an ultrasonic dispersion for 30 minutes, thereby preparing a colloidal solution containing titanium oxide particles having an average particle size (average primary particle size) of 15 nm. Thereafter, ethanol having a volume twice the volume of the obtained colloidal solution was added to the colloidal solution, and the solution was subjected to centrifugation at a rotation speed of 5,000 rpm, thereby obtaining titanium oxide particles.

In the present specification, the average particle size is a value determined from a diffraction peak of X-ray diffraction (XRD). Specifically, from the half-width of a diffraction angle in θ/2θ XRD scanning and the Scherrer equation, the average particle size is determined. For example, for anatase-type titanium oxide, the half-width of a diffraction angle (2θ=about 25.3°) corresponding to (101) plane may be measured.

Then, the obtained titanium oxide particles are washed, a solution obtained by dissolving ethyl cellulose and terpineol in anhydrous ethanol was then added thereto, and the titanium oxide particles are dispersed by stirring. Subsequently, the mixed solution is heated under a vacuum condition such that ethanol is evaporated, thereby obtaining a titanium oxide paste. The concentration is adjusted such that the finally obtained past is composed of 20% by mass (solid concentration) of titanium oxide, 10% by mass of ethyl cellulose, and 64% by mass of terpineol.

Examples of the solvent used for preparing the paste which contains semiconductor particles (or in which the semiconductor particles are suspended) include, in addition to the aforementioned solvents, a glyme-based solvent such as ethylene glycol monomethyl ether, an alcohol-based solvent such as isopropyl alcohol, a mixed solvent such as isopropyl alcohol/toluene, water, and the like.

Thereafter, the first conductive layer is coated with the paste containing semiconductor particles by the aforementioned method, followed by calcination, thereby obtaining a porous semiconductor layer. The conditions of drying and calcination, such as temperature, time, and atmosphere, need to be appropriately adjusted according to the type of the supporting substrate or the semiconductor particles used. For example, calcination can be performed for about 10 seconds to 12 hours in the atmosphere or in an inert gas atmosphere at a temperature within a range of about 50° C. to 800° C.

—Formation of Porous Insulating Layer—

The method for forming the film-like porous insulating layer 4b on the porous semiconductor layer is not particularly limited, and examples thereof include known methods. Specifically, examples of the method include (1) method of coating the porous semiconductor layer with a paste containing an insulating material by a screen printing method, an ink jet method, or the like and then performing calcination, (2) method of forming a film on the porous semiconductor layer by a CVD method, an MOCVD method, or the like using a desired raw material gas (3) method of forming a film on the porous semiconductor layer by a PVD method, a vapor deposition method, a sputtering method, or the like using a raw material solid, (4) method of forming a film on the porous semiconductor layer by a sol-gel method or a method using an electrochemical redox reaction, and the like. Among these, a screen printing method using a paste is particularly preferable because this method makes it possible to form a porous insulating layer having a large film thickness at low costs. The calcination conditions of the paste are as described above.

—Dye Adsorption Method—

Examples of the method for causing a metal complex dye represented by Formula (1) to be adsorbed onto the porous semiconductor layer (power generating layer) include a method of immersing the porous semiconductor layer formed on the first conductive layer 2 in a solution in which the metal complex dye is dissolved (solution for dye adsorption).

The solvent for dissolving a dye may be a solvent dissolving a dye, and specific examples thereof include alcohols such as ethanol, ketones such as acetone, ethers such as diethyl ether and tetrahydrofuran, nitrogen compounds such as acetonitrile, halogenated aliphatic hydrocarbons such as chloroform, aliphatic hydrocarbons such as hexane, aromatic hydrocarbons such as benzene, esters such as ethyl acetate, water, and the like.

In a case where the power generating layer (negative electrode) and the counter electrode 6 (positive electrode) are also laminated on one sheet of supporting substrate, such as a case where the film thickness of the laminate is large and the molecular weight of a dye is large, it is better to use two or more kinds of solvents dissolving the dye by mixing the solvents together, and it is preferable to control the dye adsorption speed (state) by using one or more kinds of solvents that poorly dissolves the dye and one or more kinds of solvents that can dissolve the dye. It is more preferable to use a mixed solvent including one or more kinds of nitrile compounds and one or more kinds of alcohols.

The dye concentration in the solution can be appropriately adjusted by the type of the dye and solvent used. In order to improve the absorptivity, it is preferable that the dye concentration is high. For example, the dye concentration may be equal to or higher than 4×10⁻⁴ mol/L.

Generally, in a photoelectric conversion element, the greater the dye adsorption amount, the more the light is absorbed onto a power generating layer. As a result, for example, more electric currents are generated, and the power generation efficiency (photoelectric conversion efficiency) is improved. However, in the case of the dye used in the present invention that will be described later, contrary to the aforementioned case, the power generation efficiency decreases even though the dye adsorption amount is excessive, and by setting the dye adsorption amount to a specific value, the power generation efficiency can be increased. That is, the amount of the dye adsorbed onto the power generating layer is 1.0×10⁻⁸ to 1.8×10⁻⁷ mol/cm² with respect to the surface area of the power generating layer. In a case where the dye adsorption amount is smaller than the aforementioned lower limit, the dye adsorption amount is insufficient, and the dye does not sufficiently absorb light. Consequently, for example, a short-circuit current decreases, and hence the power generation efficiency decreases in some cases. In a case where the dye adsorption amount is larger than the aforementioned upper limit, for example, a dye-mediated recombination process becomes marked. Consequently, an open voltage decreases, and hence the power generation efficiency decreases in some cases.

In a case where the dye adsorption amount is set to be a predetermined value described above, it is possible to inhibit the metal complex dye-mediated carrier recombination that occurs due to aggregation or the like. As a result, for example, an open voltage is improved, and high heat-resistant durability is exhibited (carrier recombination that increasingly occurs at the time of heating is inhibited).

The dye adsorption amount is more preferably 5.0×10⁻⁸ to 1.5×10⁻⁷ mol/cm², because then a high level of power generation efficiency and a high level of heat-resistant durability can be achieved at the same time.

In the present invention, the dye adsorption amount of the power generating layer can be measured by the method which will be described later.

In the present invention, the dye adsorption amount of the power generating layer can be set within a predetermined range by adjusting the average particle size of the insulating material forming the porous insulating layer as described above and by the film thickness of the porous insulating layer, the preparation conditions of the solution for dye adsorption, the composition of the solution, the conditions of immersion into the solution for dye adsorption, the treatment method performed after the immersion into the solution for dye adsorption, and the like.

<Formation of Counter Electrode>

Examples of the method for forming the counter electrode 6 on the power generating layer 4 include a vapor deposition method, a printing method, and the like. In a case where the counter electrode is formed by a vapor deposition method, because the film itself is porous, it is not necessary to additionally form holes through which the solution for dye adsorption or the electrolyte material moves.

In a case where holes are formed in the counter electrode 6, for example, it is possible to use a method of causing the counter electrode 6 to partially evaporate by being irradiated with laser beams.

In a case where the counter electrode 6 does not have a catalytic ability, as the method for forming the catalyst layer on any one of the surfaces of the counter electrode 6, it is possible to use known formation methods such as a screen printing method, a vapor deposition method, and a CVD method.

<Formation of Sealing Material>

The sealing material 8 is prepared by cutting out a thermal fusion film, an ultraviolet curable resin, or the like, in the shape that surrounds the periphery of the laminate.

In a case where a silicone resin, an epoxy resin, or a glass frit is used, the pattern of the sealing material 8 can be formed by using a dispenser. In a case where a hot melt resin is used, the pattern of the sealing material 8 can be formed by boring holes formed by performing patterning in a sheet-like hot melt resin.

The sealing material 8 is disposed between the first conductive layer 2 and the cover layer 7 as if bonding the first conductive layer 2 and the cover layer 7 to each other, and is fixed by heating or ultraviolet irradiation.

<Electrolyte Filling>

For example, by being injected through holes for electrolyte injection that are provided in advance in the cover layer 7, the electrolyte (carrier transport material) fills the electrolyte filling region 9. In this way, some or all of the voids provided in each of the power generating layer and the counter electrode can be filled with the electrolyte. After the injection of the electrolyte material, the holes for electrolyte injection are sealed using, for example, an ultraviolet curable resin.

<<Metal Complex Dye>>

Hereinafter, the dye used in the present invention will be described.

The dye used in the present invention is a metal complex dye represented by Formula (1).

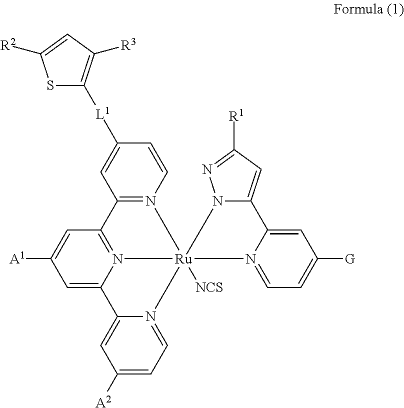

In Formula (1), R¹ represents a hydrogen atom, an alkyl group, or an aryl group. Among these, an alkyl group is preferable.

As the alkyl group which can be adopted as R¹, an alkyl group having 1 to 20 alkyl group is preferable, an alkyl group having 1 to 10 carbon atoms is more preferable, and an alkyl group having 1 to 6 carbon atoms is even more preferable. Examples of the alkyl group include methyl, ethyl, propyl, n-butyl, t-butyl, pentyl, hexyl, and the like. The alkyl group may further have a substituent. As the substituent, a halogen atom is preferable. Examples of the halogen atom include a fluorine atom, a chlorine atom, and a bromine atom. Among these, a fluorine atom is preferable. In the alkyl group substituted with a halogen atom, the number of halogen atoms substituting the alkyl group may be 1 or 2 or greater. However, an alkyl group in which all the hydrogen atoms are substituted with halogen atoms is preferable, and particularly, a perfluoroalkyl group is preferable. Examples of the alkyl group substituted with a halogen atom include fluoromethyl, difluoromethyl, trifluoromethyl, 2,2,2-trifluoroethyl, and the like.

The alkyl group represented by R¹ is preferably an alkyl group substituted with a halogen atom, more preferably an alkyl group substituted with a fluorine atom, and particularly preferably trifluoromethyl.

As the aryl group which can be adopted as R¹, an aryl group having 6 to 20 carbon atoms is preferable, and an aryl group having 6 to 12 carbon atoms is more preferable. Examples of the aryl group include phenyl, naphthyl, and the like. The aryl group may further have a substituent. As the substituent, a halogen atom is preferable. Examples of the halogen atom include a fluorine atom, a chlorine atom, and a bromine atom. Among these, a fluorine atom is preferable. In the aryl group substituted with a halogen atom, the number of halogen atoms substituting the aryl group may be 1 or 2 or greater. Examples of the aryl group substituted with a halogen atom include 4-fluorophenyl, 2,4-difluorophenyl, perfluorophenyl, and perchlorophenyl.

Among the above, as R¹, a hydrogen atom, methyl, trifluoromethyl, and perfluorophenyl are preferable, and trifluoromethyl is particularly preferable.

R² represents a hydrogen atom or an alkyl group. As the alkyl group which can be adopted as R², an alkyl group having 1 to 6 carbon atoms is preferable. Examples thereof include methyl, ethyl, n-hexyl, and the like. R² is preferably a hydrogen atom or methyl.

R³ represents an alkyl group. As the alkyl group which can be adopted as R³, an alkyl group having 1 to 12 carbon atoms is preferable. Examples thereof include methyl, ethyl, n-hexyl, n-octyl, n-decyl, n-dodecyl, and the like. R³ is more preferably an alkyl group having 1 to 6 carbon atoms.

G represents a group represented by any one of Formulae (G-1) to (G-4). Among the groups represented by Formulae (G-1) to (G-4), a group represented by Formula (G-1) is preferable.

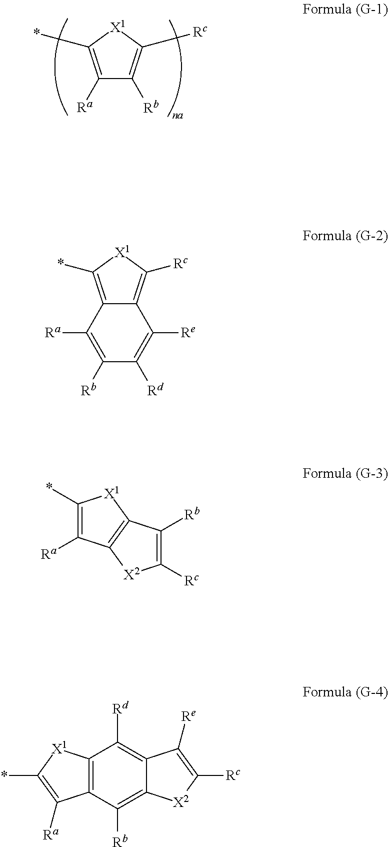

In Formulae (G-1) to (G-4), X¹ and X² each independently represent —O—, —S—, —Se—, —N(R^{A})—, —C(R^{A})₂—, or —Si(R^{A})₂—. R^{A} represents a hydrogen atom, an alkyl group, or an aryl group.

* represents a position bonded to a pyridyl group (pyridine ring).

Each of X¹ and X² is preferably a group selected from —O—, —S—, —Se—, and —N(R^{A})—. Particularly, a case where any of X¹ and X² is —S— is more preferable.

A case where X¹ in Formulae (G-1) and (G-2) is —S— is preferable.

Each of X¹ and X² in Formulae (G-3) and (G-4) is more preferably a group selected from —O— and —S—. Particularly, a case where both of X¹ and X² are —S— is preferable.

As the alkyl group which can be adopted as R^{A}, an alkyl group having 1 to 20 carbon atoms is preferable, and an alkyl group having 1 to 12 carbon atoms is more preferable. Examples of the alkyl group include methyl, ethyl, propyl, n-butyl, t-butyl, n-heptyl, n-hexyl, 2-ethylhexyl, n-pentyl, n-octyl, n-nonyl, n-decyl, n-dodecyl, and the like. The alkyl group may have a substituent. As the substituent, a halogen atom is preferable. Examples of the halogen atom include a fluorine atom, a chlorine atom, and a bromine atom. Among these, a fluorine atom is preferable. The number of halogen atoms substituting the alkyl group may be 1 or 2 or greater. Examples of the alkyl group substituted with a halogen atom include trifluoromethyl, 2,2,2-trifluoroethyl, 3,3,3-trifluoropropyl, and the like.

As the aryl group which can be adopted as R^{A}, an aryl group having 6 to 20 carbon atoms is preferable, and an aryl group having 6 to 12 carbon atoms is more preferable. Examples of the aryl group include phenyl, naphthyl, and the like. The aryl group may have a substituent. As the substituent, a halogen atom is preferable. Examples of the halogen atom include a fluorine atom, a chlorine atom, and a bromine atom. Among these, a fluorine atom is preferable. The number of halogen atoms substituting the aryl group may be 1 or 2 or greater. Examples of the aryl group substituted with a halogen atom include 4-fluorophenyl, 2,4-difluorophenyl, perfluorophenyl, and perchlorophenyl.

Among the above, as R^{A}, a hydrogen atom, methyl, hexyl, and phenyl are preferable.

na represents an integer of 1 to 3. na is preferably 1 or 2, and particularly preferably 1.

R^{a} represents an alkyl group, an alkoxy group, an alkylthio group, or an amino group. R^{b}, R^{c}, R^{d}, and R^{e} each independently represent a hydrogen atom or a substituent.

As the alkyl group which can be adopted as R^{a}, an alkyl group having 1 to 20 carbon atoms is preferable, an alkyl group having 2 to 12 carbon atoms is more preferable, an alkyl group having 4 to 12 carbon atoms is even more preferable, and an alkyl group having 6 to 8 carbon atoms is still more preferable. Examples of the alkyl group include methyl, ethyl, propyl, n-butyl, t-butyl, pentyl, hexyl, 2-ethylhexyl, heptyl, octyl, nonyl, decyl, and dodecyl. Among these, n-butyl, t-butyl, hexyl, 2-ethylhexyl, heptyl, octyl, nonyl, decyl, and dodecyl are preferable, hexyl, 2-ethylhexyl, and octyl are more preferable.

As the alkoxy group which can be adopted as R^{a}, an alkoxy group having 1 to 20 carbon atoms is preferable, an alkoxy group having 1 to 12 carbon atoms is more preferable, an alkoxy group having 4 to 12 carbon atoms is even more preferable, and an alkoxy group having 6 to 8 carbon atoms is still more preferable. Examples of the alkoxy group include methoxy, ethoxy, propoxy, n-butoxy, t-butoxy, pentoxy, hexyloxy, 2-ethylhexyloxy, heptyloxy, octyloxy, nonyloxy, decyloxy, and dodecyloxy. Among these, n-butoxy, t-butoxy, hexyloxy, 2-ethylhexyloxy, heptyloxy, octyloxy, nonyloxy, decyloxy, and dodecyloxy are preferable, and hexyloxy, 2-ethylhexyloxy, and octyloxy are more preferable.

As the alkylthio group which can be adopted as R^{a}, an alkylthio group having 1 to 20 carbon atoms is preferable, an alkylthio group having 1 to 12 carbon atoms is more preferable, an alkylthio group having 4 to 12 carbon atoms is even more preferable, and an alkylthio group having 6 to 8 carbon atoms is still more preferable. Examples of the alkylthio group include methylthio, ethylthio, propylthio, n-butylthio, t-butylthio, pentylthio, hexylthio, 2-ethylhexylthio, heptylthio, octylthio, nonylthio, decylthio, dodecylthio, and octadecylthio. Among these, n-butylthio, t-butylthio, hexylthio, 2-ethylhexylthio, heptylthio, octylthio, nonylthio, decylthio, and dodecylthio are preferable, and hexylthio, 2-ethylhexylthio, and octylthio are more preferable.

The amino group which can be adopted as R^{a} includes an amino group (—NH₂), an alkylamino group, and an arylamino group. As the amino group, an amino group having 0 to 40 carbon atoms is preferable, an amino group having 2 to 20 carbon atoms is more preferable, and an amino group having 8 to 18 carbon atoms is even more preferable.

Among the amino groups, an amino group (—NH₂) and an alkylamino group are preferable. The alkylamino group is preferably a dialkylamino group, and examples thereof include amino (—NH₂), dimethylamino, diethylamino, dipropylamino, dibutylamino, dihexylamino, diheptylamino, dioctylamino, dinonylamino, didecylamino, didodecylamino, and dioctadecylamino.

Among these, dimethylamino, diethylamino, dipropylamino, dibutylamino, dihexylamino, diheptylamino, and dioctylamino are preferable, and dibutylamino and dihexylamino are more preferable.

Among the above, as R^{a}, an alkyl group is preferable. The alkyl group is more preferably an alkyl group having 2 to 12 carbon atoms, even more preferably an alkyl group having 4 to 12 carbon atoms, and particularly preferably an alkyl group having 6 to 8 carbon atoms. Among these, as the alkyl group, a linear alkyl group is preferable.

Examples of substituent which can be adopted as R^{b}, R^{c}, R^{d}, and R^{e} include a halogen atom, an alkyl group (preferably an alkyl group having 1 to 20 carbon atoms), an alkenyl group (preferably an alkenyl group having 2 to 20 carbon atoms), an alkynyl group (preferably an alkynyl group having 2 to 20 carbon atoms), an aryl group (preferably an aryl group having 6 to 20 carbon atoms), a heterocyclic group (preferably a hetero ring having at least one heteroatom (an oxygen atom, a sulfur atom, a nitrogen atom, a silicon atom, a phosphorus atom, a selenium atom, or the like) and 2 to 20 carbon atoms as atoms constituting the ring, the hetero ring includes an aromatic ring and an aliphatic ring, and the hetero ring is preferably a 5- or 6-membered ring), an alkoxy group (preferably an alkoxy group having 1 to 20 carbon atoms), an alkylthio group (preferably an alkylthio group having 1 to 20 carbon atoms), an amino group (preferably an amino group having 0 to 40 carbon atoms), and the like.

R^{b}, R^{c}, R^{d}, and R^{e} are preferably a hydrogen atom and the aforementioned substituents, and particularly preferably a hydrogen atom.

A¹ and A² in Formula (1) each independently represent a carboxy group or a salt of a carboxy group.

In a case where each of A¹ and A² is a salt of a carboxy group, examples of the salt include a sodium salt, a potassium salt, an ammonium salt, and a pyridinium salt of a carboxy group. Among these, an ammonium salt of a carboxy group is preferable.

In ammonium forming an ammonium salt, a group substituting a nitrogen atom is preferably an alkyl group, an aralkyl group, or an aryl group. Particularly, a case where all the groups are an alkyl group is more preferable.

Examples of the ammonium salt of a carboxy group include tetrabutyl ammonium, triethylbenzyl ammonium, tetraethyl ammonium, tetrapropyl ammonium, tetrahexyl ammonium, and tetraoctyl ammonium. Among these, tetrabutyl ammonium is preferable.

A case where both of A¹ and A² represent a carboxy group or a salt of a carboxy group is preferable. In this case, a carboxy group or an ammonium salt of a carboxy group is particularly preferable. Particularly, a case where at least one of A or A² is a carboxy group is preferable.

In Formula (1), L¹ represents a group represented by any of Formulae (A-1) and (A-2).

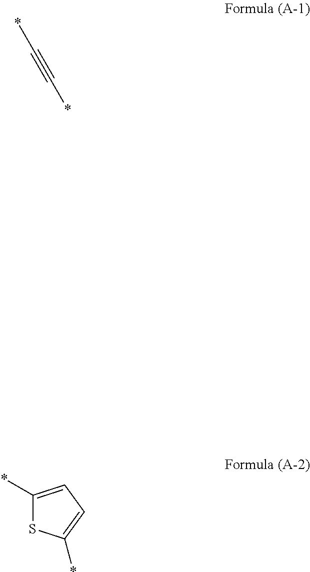

In each of the formulae, one of two *'s represents a position bonded to a thienyl group, and the other represents a position bonded to a pyridyl group.

The thiophene ring in Formula (A-2) may have a substituent.

The metal complex dye represented by Formula (1) is preferably a metal complex dye represented by Formula (2).

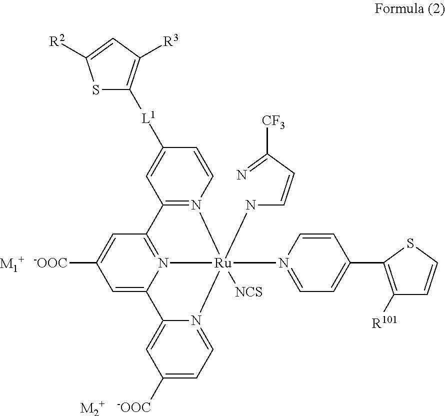

In Formula (2), M₁⁺ and M₂⁺ each independently represent a proton (H⁺) or a counterion. Among these, a proton or an ammonium ion is preferable. Particularly, a case where at least one of M₁⁺ or M₂⁺ is a proton is preferable.

Examples of ammonium ions include the ammonium exemplified above for the aforementioned ammonium salt of a carboxy group. Among these, tetrabutyl ammonium, triethylbenzyl ammonium, tetraethyl ammonium, tetrapropyl ammonium, tetrahexyl ammonium, and tetraoctyl ammonium are preferable, and tetrabutyl ammonium is particularly preferable.

R¹⁰¹ represents an alkyl group. This alkyl group has the same definition as the alkyl group which can be adopted as R^{a}, and a preferred range thereof is also the same.

Particularly, as the alkyl group which can be adopted as R¹⁰¹, an alkyl group having 2 to 12 carbon atoms is preferable, and an alkyl group having 4 to 12 carbon atoms is more preferable.

Examples of the alkyl group which can be adopted as R¹⁰¹ include methyl, ethyl, propyl, n-butyl, t-butyl, pentyl, hexyl, 2-ethylhexyl, heptyl, octyl, nonyl, decyl, dodecyl, and tetradecyl. Among these, ethyl, n-propyl, isopropyl, n-butyl, t-butyl, n-pentyl, n-hexyl, 2-ethylhexyl, heptyl, octyl, n-nonyl, n-decyl, and n-dodecyl are preferable.

L¹ represents a group represented by any of Formulae (A-1) and (A-2). L¹ has the same definition as L¹ in Formula (1), and a preferred range thereof is also the same.

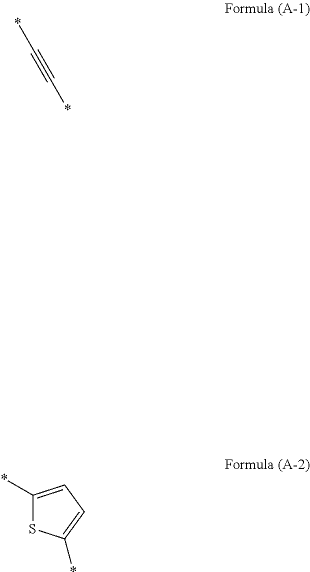

In each of the formulae, one of two *'s represents a position bonded to a thienyl group in Formula (2), and the other represents a position bonded to a pyridyl group.

R² and R³ have the same definition as R² and R³ in Formula (1) respectively, and a preferred range thereof is also the same.

Specific preferred examples of the metal complex dye represented by Formula (1) will be shown below, but the present invention is not limited thereto.

In the following specific examples, (A-1) in the column of L¹ represents a group represented by Formula (A-1), and (A-2) in the same column represents a group represented by Formula (A-2). Furthermore, in a case where any one of M₁⁺ and M₂⁺ is a counterion, for the sake of convenience, M₁⁺ is described as a counterion. However, there is also a case where M₁⁺ is a proton while M₂⁺ is a counterion.

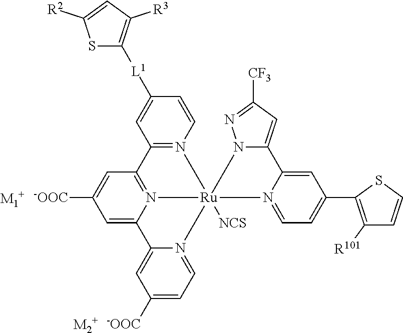

| Dye No. | L¹ | R² | R³ | R¹⁰¹ | M₁ | M₂ |
|---|---|---|---|---|---|---|
| Dye 1 | (A-1) | H | CH₃ | n-C₆H₁₃ | H⁺ | H⁺ |
| Dye 2 | (A-1) | H | CH₃ | n-C₆H₁₃ | (n-C₄H₉)₄N⁺ | H⁺ |
| Dye 3 | (A-1) | H | CH₃ | n-C₈H₁₇ | H⁺ | H⁺ |
| Dye 4 | (A-1) | H | CH₃ | n-C₈H₁₇ | (n-C₄H₉)₄N⁺ | H⁺ |
| Dye 5 | (A-1) | H | CH₃ | n-C₁₀H₂₁ | H⁺ | H⁺ |
| Dye 6 | (A-1) | H | CH₃ | n-C₁₀H₂₁ | (n-C₄H₉)₄N⁺ | H⁺ |
| Dye 7 | (A-1) | H | CH₃ | n-C₄H₉ | H⁺ | H⁺ |
| Dye 8 | (A-1) | H | CH₃ | n-C₄H₉ | (n-C₄H₉)₄N⁺ | H⁺ |
| Dye 9 | (A-1) | H | CH₃ | n-C₁₂H₂₅ | H⁺ | H⁺ |
| Dye 10 | (A-1) | H | CH₃ | n-C₁₂H₂₅ | (n-C₄H₉)₄N⁺ | H⁺ |
| Dye 11 | (A-1) | CH₃ | CH₃ | n-C₈H₁₇ | H⁺ | H⁺ |
| Dye 12 | (A-1) | CH₃ | CH₃ | n-C₈H₁₇ | (n-C₄H₉)₄N⁺ | H⁺ |
| Dye 13 | (A-1) | CH₃ | CH₃ | n-C₆H₁₃ | H⁺ | H⁺ |
| Dye 14 | (A-1) | CH₃ | CH₃ | n-C₆H₁₃ | (n-C₄H₉)₄N⁺ | H⁺ |
| Dye 15 | (A-1) | CH₃ | CH₃ | n-C₁₀H₂₁ | H⁺ | H⁺ |
| Dye 16 | (A-1) | CH₃ | CH₃ | n-C₁₀H₂₁ | (n-C₄H₉)₄N⁺ | H⁺ |
| Dye 17 | (A-1) | CH₃ | CH₃ | n-C₄H₉ | H⁺ | H⁺ |
| Dye 18 | (A-1) | CH₃ | CH₃ | n-C₄H₉ | (n-C₄H₉)₄N⁺ | H⁺ |
| Dye 19 | (A-1) | CH₃ | CH₃ | n-C₁₂H₂₅ | H⁺ | H⁺ |
| Dye 20 | (A-1) | CH₃ | CH₃ | n-C₁₂H₂₅ | (n-C₄H₉)₄N⁺ | H⁺ |
| Dye 21 | (A-1) | H | n-C₆H₁₃ | n-C₆H₁₃ | H⁺ | H⁺ |
| Dye 22 | (A-1) | H | n-C₆H₁₃ | n-C₆H₁₃ | (n-C₄H₉)₄N⁺ | H⁺ |
| Dye 23 | (A-1) | H | n-C₆H₁₃ | n-C₈H₁₇ | H⁺ | H⁺ |
| Dye 24 | (A-1) | H | n-C₆H₁₃ | n-C₈H₁₇ | (n-C₄H₉)₄N⁺ | H⁺ |
| Dye 25 | (A-1) | H | n-C₆H₁₃ | 2-Ethylhexyl | H⁺ | H⁺ |
| Dye 26 | (A-1) | H | n-C₆H₁₃ | 2-Ethylhexyl | (n-C₄H₉)₄N⁺ | H⁺ |
| Dye 27 | (A-1) | H | n-C₆H₁₃ | n-C₁₀H₂₁ | H⁺ | H⁺ |
| Dye 28 | (A-1) | H | n-C₆H₁₃ | n-C₁₀H₂₁ | (n-C₄H₉)₄N⁺ | H⁺ |
| Dye 29 | (A-1) | H | n-C₆H₁₃ | n-C₁₂H₂₅ | H⁺ | H⁺ |
| Dye 30 | (A-1) | H | n-C₆H₁₃ | n-C₁₂H₂₅ | (n-C₄H₉)₄N⁺ | H⁺ |
| Dye 31 | (A-2) | H | CH₃ | n-C₆H₁₃ | H⁺ | H⁺ |
| Dye 32 | (A-2) | H | CH₃ | n-C₆H₁₃ | (n-C₄H₉)₄N⁺ | H⁺ |
| Dye 33 | (A-2) | H | CH₃ | n-C₈H₁₇ | H⁺ | H⁺ |
| Dye 34 | (A-2) | H | CH₃ | n-C₈H₁₇ | (n-C₄H₉)₄N⁺ | H⁺ |
| Dye 35 | (A-2) | H | CH₃ | n-C₁₀H₂₁ | H⁺ | H⁺ |
| Dye 36 | (A-2) | H | CH₃ | n-C₁₀H₂₁ | (n-C₄H₉)₄N⁺ | H⁺ |
| Dye 37 | (A-2) | H | CH₃ | 2-Ethylhexyl | H⁺ | H⁺ |
| Dye 38 | (A-2) | H | CH₃ | 2-Ethylhexyl | (n-C₄H₉)₄N⁺ | H⁺ |
| Dye 39 | (A-2) | H | CH₃ | n-C₁₂H₂₅ | H⁺ | H⁺ |
| Dye 40 | (A-2) | H | CH₃ | n-C₁₂H₂₅ | (n-C₄H₉)₄N⁺ | H⁺ |
| Dye 41 | (A-2) | CH₃ | CH₃ | n-C₆H₁₃ | H⁺ | H⁺ |
| Dye 42 | (A-2) | CH₃ | CH₃ | n-C₆H₁₃ | (n-C₄H₉)₄N⁺ | H⁺ |
| Dye 43 | (A-2) | CH₃ | CH₃ | n-C₈H₁₇ | H⁺ | H⁺ |
| Dye 44 | (A-2) | CH₃ | CH₃ | n-C₈H₁₇ | (n-C₄H₉)₄N⁺ | H⁺ |
| Dye 45 | (A-2) | CH₃ | CH₃ | n-C₁₀H₂₁ | H⁺ | H⁺ |
| Dye 46 | (A-2) | CH₃ | CH₃ | n-C₁₀H₂₁ | (n-C₄H₉)₄N⁺ | H⁺ |
| Dye 47 | (A-2) | CH₃ | CH₃ | 2-Ethylhexyl | H⁺ | H⁺ |
| Dye 48 | (A-2) | CH₃ | CH₃ | 2-Ethylhexyl | (n-C₄H₉)₄N⁺ | H⁺ |
| Dye 49 | (A-2) | CH₃ | CH₃ | n-C₁₂H₂₅ | H⁺ | H⁺ |
| Dye 50 | (A-2) | CH₃ | CH₃ | n-C₁₂H₂₅ | (n-C₄H₉)₄N⁺ | H⁺ |
| Dye 51 | (A-2) | CH₃ | n-C₆H₁₃ | n-C₆H₁₃ | H⁺ | H⁺ |
| Dye 52 | (A-2) | CH₃ | n-C₆H₁₃ | n-C₆H₁₃ | (n-C₄H₉)₄N⁺ | H⁺ |
| Dye 53 | (A-2) | CH₃ | n-C₆H₁₃ | n-C₈H₁₇ | H⁺ | H⁺ |
| Dye 54 | (A-2) | CH₃ | n-C₆H₁₃ | n-C₈H₁₇ | (n-C₄H₉)₄N⁺ | H⁺ |
| Dye 55 | (A-2) | CH₃ | n-C₆H₁₃ | n-C₁₀H₂₁ | H⁺ | H⁺ |
| Dye 56 | (A-2) | CH₃ | n-C₆H₁₃ | n-C₁₀H₂₁ | (n-C₄H₉)₄N⁺ | H⁺ |
| Dye 57 | (A-2) | CH₃ | n-C₆H₁₃ | 2-Ethylhexyl | H⁺ | H⁺ |
| Dye 58 | (A-2) | CH₃ | n-C₆H₁₃ | 2-Ethylhexyl | (n-C₄H₉)₄N⁺ | H⁺ |
| Dye 59 | (A-2) | CH₃ | n-C₆H₁₃ | n-C₁₂H₂₅ | H⁺ | H⁺ |
| Dye 60 | (A-2) | CH₃ | n-C₆H₁₃ | n-C₁₂H₂₅ | (n-C₄H₉)₄N⁺ | H⁺ |

The metal complex dye represented by Formula (1) can be synthesized based on the general method for synthesizing a Ru metal complex dye. The specific synthesis method of the metal complex dye represented by Formula (1) is described in examples by using a metal complex dye Dye21 or the like. Metal complex dyes other than the metal complex dye synthesized in examples can also be synthesized based on the specific synthesis method shown in examples.

### EXAMPLES

<Synthesis Example of Metal Complex Dye>

Hereinafter, the synthesis method of the metal complex dye will be specifically described by using the following synthesis examples, but the starting material, the dye intermediate, and the synthesis route are not limited to the synthesis examples. In the present specification, room temperature means 25° C.

(Synthesis of Metal Complex Dye Dye21)

According to the following scheme, a metal complex dye Dye21 was synthesized.

In the following scheme, TMS represents trimethylsilyl, and Et represents ethyl.

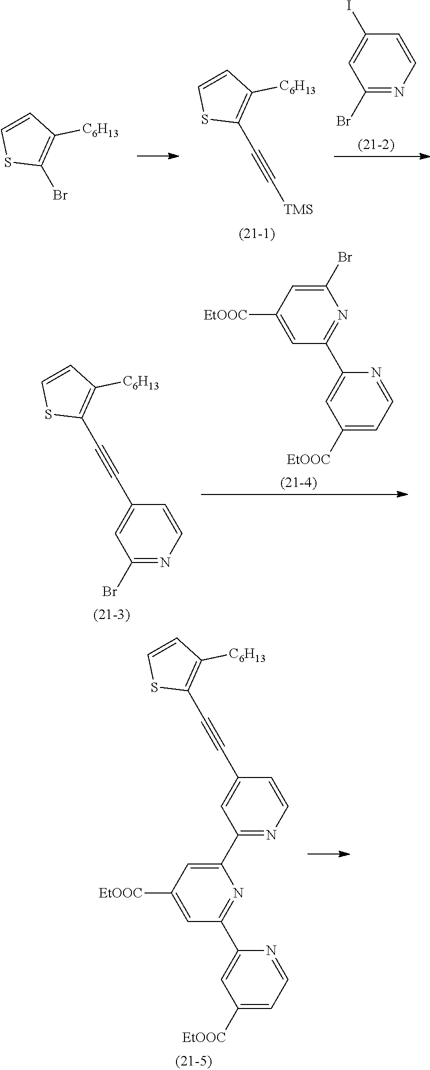

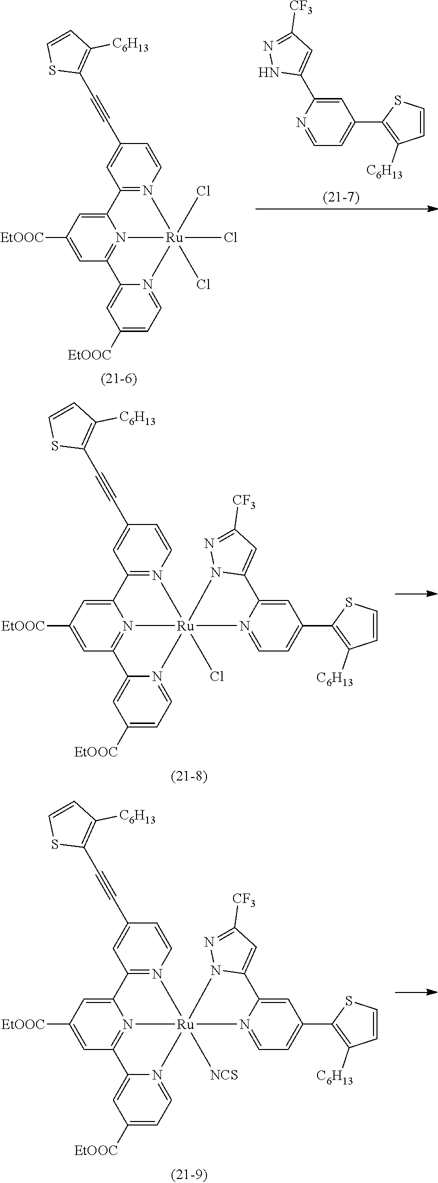

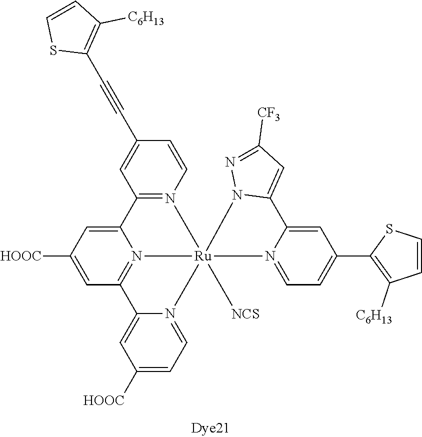

(i) Synthesis of Compound (21-1)

Tetrahydrofuran (THF) (20 mL) was added to a mixture of 1.73 g (7 mmol) of 2-bromo-3-hexylthiophene, 1.94 mL (14 mmol) of trimethylsilylacetylene, 53 mg of dichlorobis(acetonitrile)palladium (II), 26.7 mg of copper (I) iodide, and 3.9 mL of triethylamine, and the mixture was deaerated by repeating pressure reduction and nitrogen gas purging three times. Tri t-butylphosphine (51 μL) was added thereto, and by stirring the mixture at room temperature, a reaction was performed for 19 hours. An aqueous saturated ammonium chloride solution and ethyl acetate were added to the obtained reaction solution, and the reaction product was extracted. The organic phase was dried over sodium sulfate, sodium sulfate was filtered, and the residue was concentrated. The concentrated residue was purified by silica gel column chromatography (eluent: hexane), thereby obtaining 1.3 g (yield: 70%) of a compound (21-1).

Identification of Compound (21-1)

MS(ESI⁺) m/z: 265.1 ([M+H]⁺)

Chemical shift σ (ppm) by ¹H-NMR (400 MHz, solvent: CDCl₃, internal reference substance: tetramethylsilane (TMS)): 0.23 (9H, s), 0.88 (3H, t), 1.25-1.35 (6H, m), 1.55-1.65 (2H, m), 2.68 (2H, t), 6.80 (1H, d), 7.09 (1H, d)

(ii) Synthesis of Compound (21-3)

Toluene (50 mL) was added to a mixture of 1.06 g (4 mmol) of the compound (21-1) and 1.13 g (4 mmol) of a compound (21-2), and the mixture was deaerated by repeating pressure reduction and nitrogen gas purging three times. Tetrakis(triphenylphosphine)palladium (0) (230 mg (0.2 mmol)), 228 mg (1.2 mmol) of copper (I) iodide, 1.84 mL of triethylamine, and 4 mL of tetrabutylammonium fluoride (1 M THF solution) were added thereto, and by stirring the mixture at room temperature, a reaction was performed for 22 hours. An aqueous saturated sodium chloride solution and ethyl acetate were added to the obtained reaction solution, and the reaction product was extracted. The organic phase was dried over sodium sulfate, sodium sulfate was filtered, and the residue was concentrated. The concentrated residue was purified by silica gel column chromatography (eluent: ethyl acetate/hexane=1/9 to 1/6), thereby obtaining 1.27 g (yield: 91%) of a compound (21-3).

Identification of Compound (21-3)

MS(ESI⁺) m/z: 348.0 ([M+H]⁺)

Chemical shift σ (ppm) by ¹H-NMR (400 MHz, solvent: CDCl₃, internal reference substance: tetramethylsilane (TMS)): 0.88 (3H, t), 1.25-1.40 (6H, m), 1.55-1.70 (2H, m), 2.74 (2H, t), 6.90 (1H, d), 7.23-7.31 (2H, m), 7.52 (1H, d), 8.32 (1H, d)

(iii) Synthesis of Compound (21-5)

The compound (21-3) (0.836 g (2.4 mmol)) was dissolved in 20 mL of toluene, and the obtained solution was deaerated by repeating pressure reduction and nitrogen gas purging three times. Tetrakis(triphenylphosphine)palladium (0) (139 mg (0.12 mmol)) and 0.944 g (2.88 mmol) of hexamethyldistannane were added thereto, and by heating the mixture under reflux, a reaction was performed for 4.5 hours. The obtained reaction solution was left to cool down to room temperature, insoluble matters were removed by being filtered through celite, and the residue was concentrated. Toluene (20 mL) and 0.758 g (2 mmol) of a compound (21-4) were added to the concentrated residue, and the obtained mixed solution was deaerated by repeating pressure reduction and nitrogen gas purging three times. Tetrakis(triphenylphosphine)palladium (0) (139 mg (0.12 mmol)) was added thereto, and by heating the obtained mixture under reflux, a reaction was performed for 3 hours. The obtained reaction solution was left to cool, insoluble matters were removed by being filtered through celite, and the residue was concentrated, thereby obtaining a crude product. The obtained crude product was purified by silica gel column chromatography (eluent: ethyl acetate/hexane=1/9 to 1/4) and recrystallized from a mixed solution of methylene chloride/methanol, thereby obtaining 0.67 g (yield: 59%) of a compound (21-5).

Identification of Compound (21-5)

MS(ESI⁺) m/z: 568.2 ([M+H]⁺)

Chemical shift Γ (ppm) by ¹H-NMR (400 MHz, solvent: CDCl₃, internal reference substance: tetramethylsilane (TMS))=0.83 (3H, t), 1.22-1.42 (6H, m), 1.45 (6H, q), 1.68-1.76 (2H, m), 2.82 (2H, t), 4.46 (4H, t), 6.90 (1H, d), 7.23-7.31 (2H, m), 7.42 (1H, d), 7.91 (1H, d), 8.68 (1H, s), 8.72 (1H, d), 8.88 (1H, d), 9.01 (2H, s), 9.12 (1H, d)

(iv) Synthesis of Compound (21-6)

The compound (21-5) (0.5 g), 240 mg of RuCl₃.xH₂O, and 50 mL of ethanol were put into a 200 mL eggplant-shaped flask, and heated and stirred for 5.5 hours at an external temperature of 100° C. The obtained reaction solution was allowed to return to room temperature, filtered, and dried, thereby obtaining 0.615 g of a compound (21-6).

(v) Synthesis of Compound (21-8)

The compound (21-6) (0.615 g), 0.301 g of a compound (21-7), 0.75 mL of tripropylamine, and 8 mL of diglyme were put into a 200 mL eggplant-shaped flask, and heated and stirred for 4 hours at an external temperature of 130° C. The obtained reaction solution was allowed to return to room temperature and then concentrated under reduced pressure. The concentrated residue was purified by silica gel column chromatography (eluent: ethyl acetate/methylene chloride=1/20 to 1/10), thereby obtaining 0.500 g of a compound (21-8).

Identification of Compound (21-8)

MS(ESI⁺) m/z: 1083.2 ([M+H]⁺)

(vi) Synthesis of compound (21-9)

The compound (21-8) (0.50 g), 0.176 g of NH₄SCN, 6 mL of N,N-dimethylformamide (DMF), and 0.6 mL of distilled water were put into an eggplant-shaped flask, and heated and stirred for 4 hours at an external temperature of 100° C. The obtained reaction solution was allowed to return to room temperature and concentrated under reduced pressure. Then, the concentrated residue was purified by silica gel column chromatography (eluent: ethyl acetate/methylene chloride=1/50), thereby obtaining 0.51 g of a compound (21-9)

Identification of Compound (21-9)

MS(ESI⁺) m/z: 1106.2 ([M+H]⁺)

(vii) Synthesis of Metal Complex Dye Dye21

The compound (21-9) (0.51 g), 1.54 mL of a 3N aqueous NaOH solution, 15 mL of THF, and 15 mL of methanol were put into an eggplant-shaped flask, and stirred for 1.5 hours at room temperature. The obtained solution was concentrated under reduced pressure, and then 40 mL of methanol was added thereto. The solution was adjusted to become acidic by using a methanol solution of trifluoromethanesulfonic acid, and the precipitated crystals were collected by filtration, washed with ultrapure water, and dried, thereby obtaining 0.345 g of a metal complex dye Dye21.

Identification of Metal Complex Dye Dye21

MS(ESI⁺) m/z: 1050.2 ([M+H]⁺)

(Synthesis of Metal Complex Dye Dye22)

The metal complex dye Dye21 was dissolved in 1 equivalent of tetrabutylammonium hydroxide methanol, the solvent methanol was concentrated to dryness, and the residue was dried under reduced pressure, thereby synthesizing a metal complex dye Dye22.

(Synthesis of Metal Complex Dye Dye51)

According to the following scheme, a metal complex dye Dye51 was synthesized.

In the following scheme, BPin represents boronic acid pinacol ester, Bu represents butyl, and Et represents ethyl.

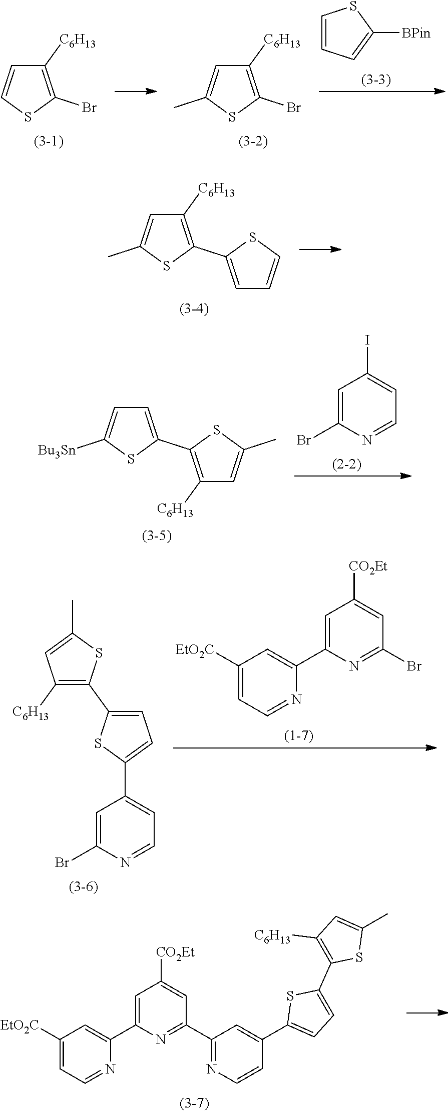

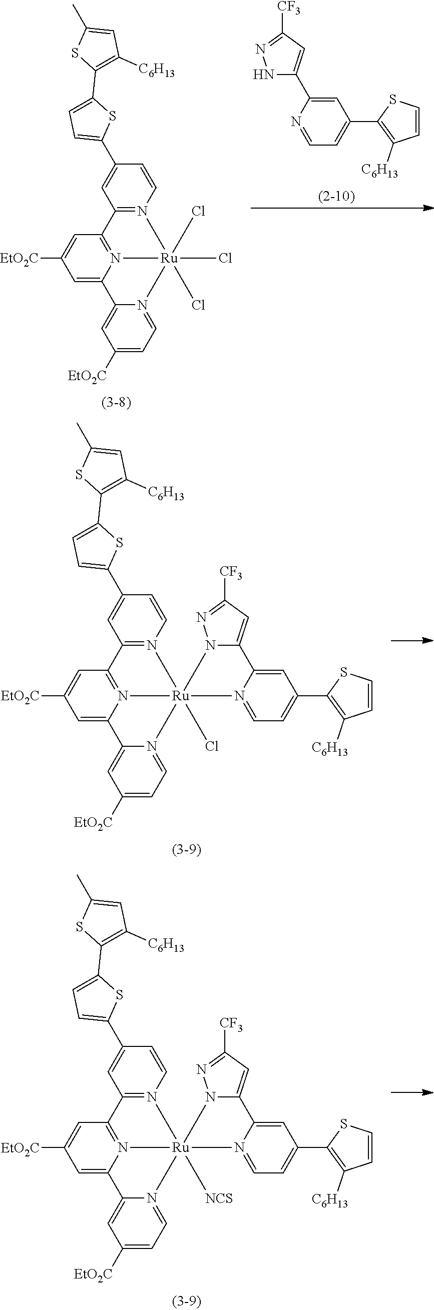

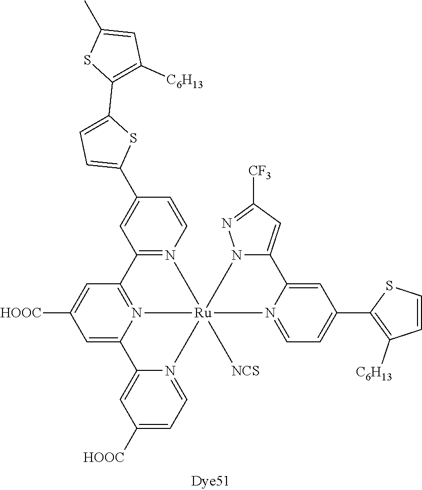

(i) Synthesis of Compound (3-2)

THF (200 mL) and a compound (3-1) (10 g) were put into a 500 mL three-neck flask, and cooled to −40° C. in a nitrogen atmosphere. Lithium diisopropylamide (LDA, 2.0 equivalents) was added thereto, and the mixed solution was stirred for 30 minutes at −40° C. Then, methyl p-toluenesulfonate (MeOTs, 16.6 g, 2.2 equivalents) was added thereto, and the solution was stirred for 3 hours at room temperature. H₂O (50 mL) was added to the obtained solution, and the reaction product was extracted using hexane. The organic phase was concentrated, and the concentrated residue was purified by silica gel column chromatography, thereby obtaining 12.1 g of a compound (3-2).

(ii) Synthesis of Compound (3-4)

THF (160 mL), H₂O (16 mL), the compound (3-2) (14 g), a compound (3-3) (13.5 g), chloro[(tri-tert-butylphosphine)-2-(2-aminobiphenyl)]palladium (II) (0.82 g), and K₃PO₄ (17 g) were put into a 500 mL three-neck flask, and the mixture was heated under reflux in a nitrogen atmosphere. The obtained solution was allowed to return to room temperature, filtered through celite, and concentrated. The concentrated residue was purified by silica gel column chromatography, thereby obtaining 14.2 g of a compound (3-4).

(iii) Synthesis of Compound (3-6)

The compound (3-4) (12 g) and THF (150 mL) were put into a 500 mL three-neck flask, and cooled to −78° C. in a nitrogen atmosphere. n-BuLi (1.6 M hexane solution, 35 mL) was added thereto, and the mixed solution was stirred for 15 minutes at −78° C. Then, Bu₃SnCl (13 mL) was added to the mixed solution, and the solution was stirred at room temperature. The obtained solution was neutralized using ammonium chloride, and the reaction product was extracted using ethyl acetate. The organic phase was concentrated, thereby obtaining a compound (3-5).

The obtained compound (3-5), a compound (2-2) (10.7 g), Pd(PPh₃)₄ (2.1 g), and toluene (150 mL) were put into a 500 mL eggplant-shaped flask, and the mixture was stirred at 110° C. in a nitrogen atmosphere. The obtained solution was allowed to return to room temperature and concentrated, and the concentrated residue was purified by silica gel column chromatography, thereby obtaining 14 g of a compound (3-6).

(iv) Synthesis of Compound (3-7)

The compound (3-6) (6 g), toluene (100 mL), Pd(PPh₃)₄ (1.6 g), and Me₃SnSnMe₃ (3.6 mL) were put into a 300 mL three-neck flask, and the mixture was heated under reflux for 3 hours in a nitrogen atmosphere. The obtained solution was allowed to return to room temperature, 50 mL of H₂O was added thereto, and the solution was filtered through celite. The reaction product was extracted using toluene. The organic phase was concentrated, and the concentrated residue was dried at 50° C. The obtained Sn substance was put into a 300 mL three-neck flask, and toluene (100 mL), Pd(PPh₃)₄ (1.6 g), and a compound (1-7) (5.4 g) were added thereto. The mixture was heated under reflux for 2 hours in a nitrogen atmosphere. The obtained solution was allowed to return to room temperature and concentrated, and the concentrated residue was purified by silica gel column chromatography, thereby obtaining 5.5 g of a compound (3-7).

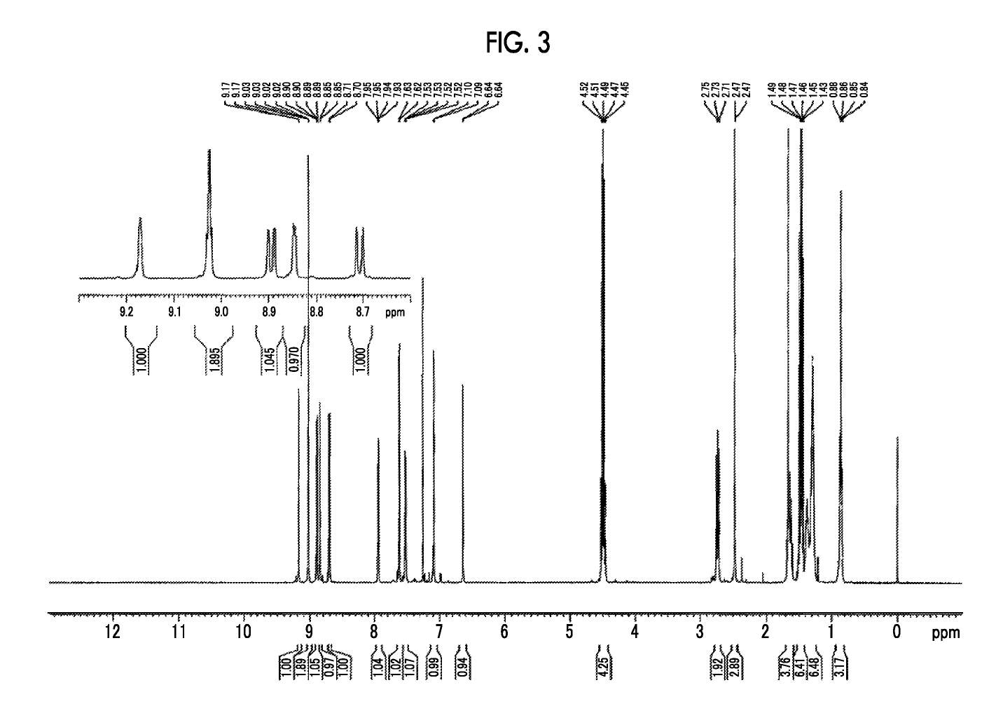

The ¹H-NMR spectrum (400 MHz, solvent: CDCl₃, internal reference substance: TMS) of the obtained compound (3-7) is shown in FIG. 3.

(v) Synthesis of Compound (3-8)

The compound (3-7) (2 g), ruthenium chloride (0.82 g), and ethanol (30 mL) were put into a 50 mL eggplant-shaped flask, and the mixture was heated under reflux for 3 hours in a nitrogen atmosphere. The precipitate was collected by filtration and washed with ethanol, thereby obtaining 2.4 g of a compound (3-8).

(vi) Synthesis of Compound (3-9)

The compound (3-8) (0.5 g), a compound (2-10) (0.22 g), diglyme (diethylene glycol dimethyl ether, 10 mL), and tripropylamine (0.6 mL) were put into a 50 mL eggplant-shaped flask. The mixture was immersed in a bath heated to 130° C. in a nitrogen atmosphere and heated for 3 hours. The reaction mixture was allowed to return to room temperature and then concentrated, and the concentrated residue was purified by silica gel column chromatography, thereby obtaining 0.36 g of a compound (3-9).

(vii) Synthesis of Compound (3-10)

The compound (3-9) (0.36 g), ammonium thiocyanate (0.24 g), DMF (40 mL), and H₂O (4 mL) were put into a 100 mL three-neck flask, and the mixture was heated for 2 hours at 100° C. The reaction mixture was allowed to return to room temperature and then concentrated, and the concentrated residue was purified by silica gel column chromatography, thereby obtaining 0.25 g of a compound (3-10).

(viii) Synthesis of Metal Complex Dye Dye51

The compound (3-10) (250 mg), DMF (44 mL), and a 1N aqueous NaOH solution (2.2 mL) were put into a 100 mL eggplant-shaped flask, and the mixture was reacted at room temperature. Trifluoromethanesulfonic acid (TfOH) was added to the obtained solution such that the pH thereof was adjusted to become 2.9. The precipitate was collected by filtration and washed with ultrapure water, thereby obtaining 227 mg of a metal complex dye Dye51.

Identification of Metal Complex Dye Dye51

MS(ESI⁺) m/z: 1122 ([M+H]⁺)

(Synthesis of Metal Complex Dye Dye52)

The metal complex dye Dye51 was dissolved in 1 equivalent of tetrabutylammonium hydroxide methanol, the solvent methanol was concentrated to dryness, and the residue was dried under reduced pressure, thereby synthesizing a metal complex dye Dye52.

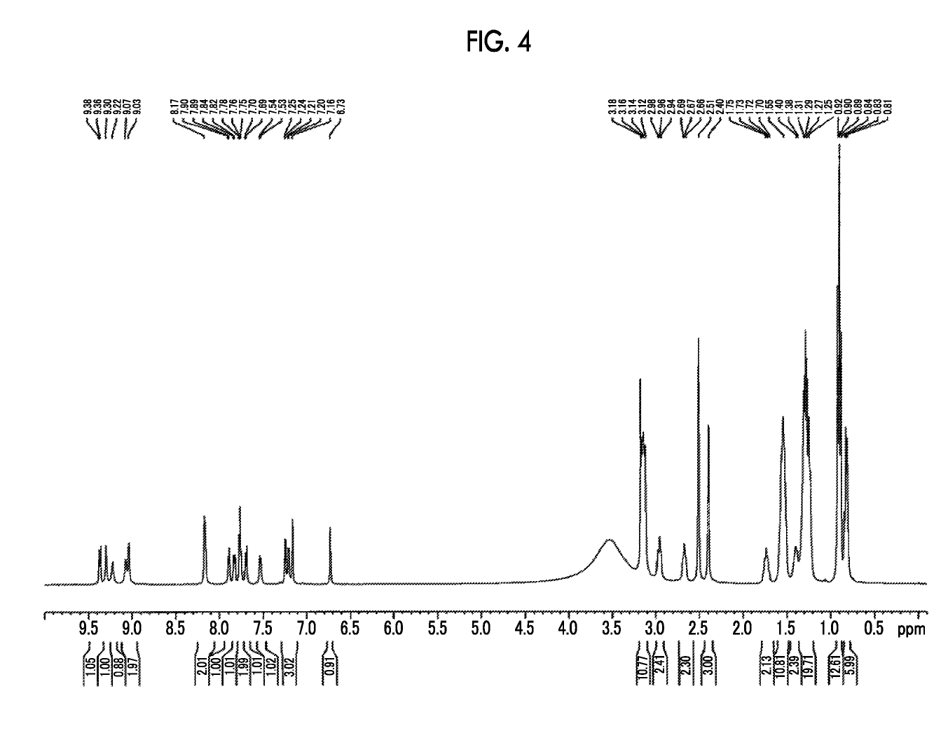

The ¹H-NMR spectrum (400 MHz, solvent: dimethylsulfoxide-d6 (DMSO-d6), internal reference substance: TMS) of the obtained metal complex dye Dye52 is shown in FIG. 4.

Metal complex dyes Dye23, Dye24, Dye25, and Dye26 were synthesized in the same manner as that described above.

### Examples 1 to 7

The photoelectric conversion module 20 shown in FIG. 2 was prepared by the following method.

A 70 mm×70 mm×4 mm (thickness) glass substrate (manufactured by Nippon Sheet Glass Co., Ltd., glass with SnO₂ film) was prepared in which the first conductive layer 2 formed of a fluorine-doped SnO₂ film was formed on the supporting substrate 1 formed of glass.

(i) Cutting First Conductive Layer 2 (Transparent Conductive Layer)

The first conductive layer 2 was irradiated with laser beams (YAG laser, fundamental wavelength: 1.06 μm, manufactured by SEISHIN TRADING CO., LTD) such that SnO₂ evaporated. In this way, a scribing process was performed to form seven linear scribes.

(ii) Preparation of Porous Semiconductor Layer 4a

A commercially available titanium oxide paste (manufactured by Solaronix SA, tradename: Ti-Nanoxide D/SP, average particle size: 13 nm) was printed on the first conductive layer 2 on the glass substrate by using a screen printing machine LS-34TVA (manufactured by NEWLONG SEIMITSU KOGYO CO., LTD) such that the scribe lines 3 were interposed between 7 rectangles. Then, the resultant was preliminarily dried for 30 minutes at 300° C. and then calcined for 40 minutes at 500° C., and these steps were performed twice. As a result, as a porous semiconductor layer 4a, a titanium oxide film having a film thickness of 12 μm was obtained.

(iii) Preparation of Porous Insulating Layer 4b

Fine particles of zirconium oxide (average particle size: 100 nm, manufactured by C. I. Kasei CO., LTD) were dispersed in terpineol and mixed with ethyl cellulose, thereby preparing a paste.

In Examples 1 to 6, by using the aforementioned printing machine LS-34TVA (manufactured by NEWLONG SEIMITSU KOGYO CO., LTD), the zirconium oxide paste prepared as above was printed on the aforementioned titanium oxide film such that the paste reached the scribe line 3 from the titanium oxide film as shown in FIG. 2. The resultant was preliminarily dried for 30 minutes at 300° C. and then calcined for 40 minutes at 500° C. In this way, as the porous insulating layer 4b, a zirconium oxide film having a film thickness of 6 μm was prepared.

In Example 7, by using a titanium oxide paste (manufactured by JGC C&C., average particle size of about 400 nm) instead of the aforementioned zirconium oxide paste, a titanium oxide film having a film thickness of 6 μm was prepared as the porous insulating layer 4b in the same manner as that used for preparing the aforementioned zirconium oxide film.

The average particle size described above was checked by the observation using a scanning electron microscope (SEM) (VE-8800, manufactured by KEYENCE CORPORATION.)

(iv) Preparation of Counter Electrode Conductive Layer 6

By using a vapor deposition machine (model name: ei-5, manufactured by ULVAC, Inc.), a film formed of platinum (catalyst layer 6a) was formed at 0.01 nm/s on the aforementioned porous insulating layer. The film thickness was 100 nm. Then, by using the vapor deposition machine (model name: ei-5, manufactured by ULVAC, Inc.), a film formed of titanium (second conductive layer 6b) was formed at 0.5 nm/s on the aforementioned film formed of platinum. The film thickness was 1,000 nm.

In this way, on a surface of the supporting substrate 1, a laminate was formed in which the first conductive layer 2, the power generating layer 4 onto which a metal complex dye was not adsorbed, and the counter electrode 6 were laminated in this order.

(v) Adsorption of Metal Complex Dye Represented by Formula (1)

Thereafter, in a solution for dye adsorption containing the metal complex dye shown in Table 1, the laminate prepared as above was immersed for 60 hours at room temperature. Then, the laminate was washed with ethanol and then dried for about 5 minutes at a temperature of about 60° C. In this way, the metal complex dye was adsorbed onto the power generating layer 4.

Herein, the solution for dye adsorption was prepared by dissolving the metal complex dye in acetonitrile:t-butanol=1:1 such that the concentration of the metal complex dye became 4×10⁻⁴ mol/L.

(vi) Preparation of Electrolyte

Iodine (manufactured by Sigma-Aldrich Co. LLC.) was added to 3-methoxypropionitrile (manufactured by Sigma-Aldrich Co. LLC.) such that the concentration became 0.15 mol/L, and dimethylpropylimidazole iodide (DMPII, manufactured by SHIKOKU CHEMICALS CORPORATION) was added thereto such that the concentration became 0.8 mol/L. Furthermore, guanidine thiocyanate (manufactured by Sigma-Aldrich Co. LLC.) was added thereto such that the concentration became 0.1 mol/L, and then N-methylbenzimidazol (manufactured by Sigma-Aldrich Co. LLC.) was added thereto such that the concentration became 0.5 mol/L. The solution was stirred for 30 minutes by using a stirrer, thereby preparing an electrolyte.

(vii) Preparation of Photoelectric Conversion Module

Separately prepared cover glass (cover 7) was superposed on the aforementioned laminate having the power generating layer 4 onto which each of the metal complex dyes was adsorbed. Thereafter, the lateral surface of the cover glass and the laminate was sealed with a resin 3035B (manufactured by ThreeBond Holdings Co., Ltd.). Then, the electrolyte was injected thereinto through the holes formed in the cover glass, and a lead wire was mounted on each electrode, thereby obtaining the photoelectric conversion module 20 (module obtained by connecting seven photoelectric conversion elements 10 in series) shown in FIG. 2.

The seal (resin 3035B) was applied using a desk-top coating robot (SM400DS-S, manufactured by Musashi Engineering, Inc). As the coating conditions, a jetting pressure was set to be 120 KPa, and a coating rate was set to be 10 mm/s.

In the prepared photoelectric conversion module 20, the film thickness of each layer was measured using a stylus-type profilometer (Dektak 150, manufactured by ULVAC Technologies, Inc.) under the conditions of a stylus radius of 12.5 μm, a stylus pressure of 3.0 mg, and a horizontal resolution of 0.5 μm/sample.

### Comparative Examples 1 and 2

Photoelectric conversion modules were prepared in the same manner as that in Example 1, except that, instead of the aforementioned metal complex dye, S—1 dye shown below was used in Comparative Example 1 while S—2 dye shown below was used in Comparative Example 2.

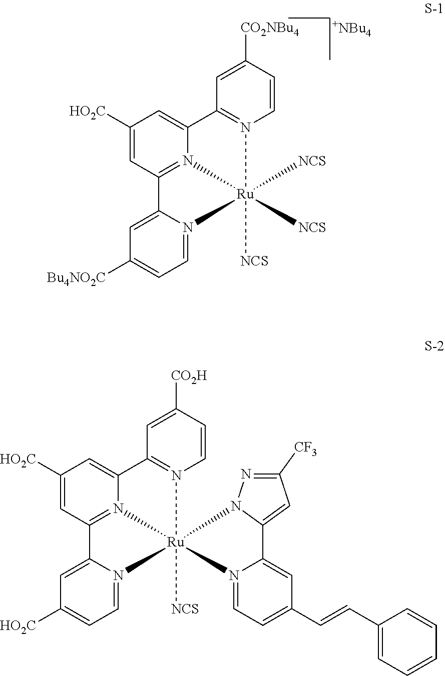

Each of the photoelectric conversion modules of Examples 1 to 7 and Comparative Examples 1 and 2 prepared as above was evaluated in terms of the dye adsorption amount and the characteristics by the following testing method. The obtained results are summarized in the following Table 1.

(Dye Adsorption Amount)

The dye adsorption amount of the photoelectric conversion module was measured as below.

The cover glass was separated from the glass with a transparent conductive film (TCO) which is a module substrate, and the module substrate was shaken in a state of being immersed in an acetonitrile solution so as to remove the electrolytic solution contained in the conductive film from the porous layer (voids).

Then, the module substrate was immersed in the following concentration adjustment solution (25° C.) for 24 hours. The disassembled element was taken out of the concentration adjustment solution, and an absorbance of the solution at a maximum absorption wavelength was measured using a spectrophotometer (model: UV-1800, manufactured by Shimadzu Corporation). From the measured absorbance, the adsorption amount was calculated using the following calibration curve. The adsorption amount calculated in this way was converted into an adsorption amount per projection area of 1 cm² of the power generating layer and taken as a dye adsorption amount (mol/cm²).

The projection area of the power generating layer is a projection area obtained in a case where the power generating layer 4 having a rectangular planar shape is irradiated with parallel light in a direction perpendicular to the top surface of the power generating layer 4. The projection area was calculated by measuring length and width of the formed projection by using calipers and multiplying the length by the width.

The calibration curve was created as below.

Methanol was added to a 40% aqueous solution of tetrabutylammonium hydroxide (TBAOH) (manufactured by Sigma-Aldrich Co. LLC., Tetrabutylammonium hydroxide solution, technical, ˜40% in H₂O) such that the concentration of TBAOH became 0.1 M. The metal complex dyes to be measured were dissolved in the concentration adjustment solution at any concentration (0.02 mM, 0.04 mM, 0.06 mM, 0.08 mM, and 0.10 mM), and each of these solutions was measured using the aforementioned spectrophotometer. By using the absorbance at a maximum absorption wavelength, a calibration curve showing the relationship between the concentration of the metal complex dye and the absorbance at a maximum absorption wavelength was created.

(Testing of Battery Characteristics)

By performing testing of battery characteristics on the photoelectric conversion modules, a photoelectric conversion efficiency η was measured. The testing of battery characteristics was performed using a solar simulator “PEC-L15” (manufactured by Peccell Technologies, Inc.) by irradiating each of the photoelectric conversion modules with simulated solar rays at 1,000 W/m² from a xenon lamp that passed through an AM 1.5 filter. By using a sourcemeter “Keithley 2401” (manufactured by TEKTRONIX, INC), the current-voltage characteristics of each of the photoelectric conversion modules irradiated with the simulated solar rays were measured, and the photoelectric conversion efficiency (η/%) was determined.

(Testing of Heat-Resistant Durability)

As testing of heat-resistant durability, each of the photoelectric conversion modules was held for 200 hours in a constant-temperature tank with a temperature of 85° C., the temporal change in the photoelectric conversion efficiency of each of the photoelectric conversion modules was measured, and a decay rate of the photoelectric conversion efficiency was determined.

The decay rate of the photoelectric conversion efficiency was calculated according to the following equation. The lower the decay rate of the photoelectric conversion efficiency is, the further the heat-induced decrease in the photoelectric conversion efficiency is inhibited (the better the heat-resistant durability is).

In the following equation, a photoelectric conversion efficiency measured after each of the photoelectric conversion modules was held for 200 hours in the constant-temperature tank with a temperature of 85° C. is represented by η_{200 hr}, and a photoelectric conversion efficiency measured before each of the photoelectric conversion modules was held in the constant-temperature tank with a temperature of 85° C. is represented by η.

Decay rate of photoelectric conversion efficiency=(n−η_{200 hr})÷η×100

In Table 1, the photoelectric conversion efficiency r) is represented by “Effi.”, and the decay rate of the photoelectric conversion efficiency is represented by “rate of performance deterioration”.

Table 1 also shows the results of a short-circuit current density (Jsc), an open voltage (Voc), and a fill factor (FF) measured in the testing of battery characteristics.

TABLE 1

| | | Dye | | | | | Rate of |
|---|---|---|---|---|---|---|---|
| | | adsorption | | | | | performance |
| | | amount | Jsc | Voc | | Effi. | deterioration |
| | Dye No. | (10⁻⁸ mol/cm²) | (mA/cm²) | (V) | FF | (%) | (%) |
| Example 1 | Dye22 | 8.7 | 2.65 | 5.21 | 0.71 | 9.81 | 4 |
| Example 2 | Dye23 | 7.8 | 2.62 | 5.17 | 0.71 | 9.62 | 6 |
| Example 3 | Dye24 | 8 | 2.64 | 5.25 | 0.70 | 9.71 | 5 |
| Example 4 | Dye25 | 7.4 | 2.60 | 5.03 | 0.70 | 9.17 | 6 |
| Example 5 | Dye26 | 7.2 | 2.60 | 5.09 | 0.70 | 9.28 | 5 |
| Example 6 | Dye52 | 8.2 | 2.68 | 5.24 | 0.71 | 9.98 | 4 |
| Example 7 | Dye22 | 8.1 | 2.58 | 4.99 | 0.70 | 9.01 | 5 |
| Comparative | S-1 | 5 | 2.26 | 4.83 | 0.67 | 7.32 | 47 |
| Example 1 | | | | | | | |
| Comparative | S-2 | 7.8 | 2.28 | 4.76 | 0.68 | 7.36 | 32 |
| Example 2 | | | | | | | |

From the results shown in Table 1, it was understood that by causing the metal complex dye represented by Formula (1) to be adsorbed onto the power generating layer in a specific adsorption amount, both the photoelectric conversion efficiency and the heat-resistant durability can be improved.

### Examples 8 to 10

Photoelectric conversion modules of Examples 8 to 10 were prepared in the same manner as that in Example 1, except that in Example 1, the film thickness of the porous insulating layer was set to be 3 μm, 6 μm, and 12 μm, and the adsorption amount of the metal complex dye was changed.

Furthermore, photoelectric conversion modules of Comparative Examples 3 to 6 were prepared in the same manner as that in Example 1, except that in Example 1, the film thickness of the porous insulating layer was set to be 0 μm (no porous insulating layer was formed), 1.5 μm, 15 μm, and 20 μm, and the adsorption amount of the metal complex dye was changed.

For each of the prepared photoelectric conversion modules of Examples 8 to 10 and Comparative Examples 3 to 6, the testing of battery characteristics and the testing of heat-resistant durability were performed in the same manner as that in Example 1. The results are shown in Table 2.

TABLE 2

| | Film thickness of | Dye | | | | | Rate of |
|---|---|---|---|---|---|---|---|
| | porous insulating | adsorption | | | | | performance |
| | layer | amount | Jsc | Voc | | Effi. | deterioration |
| | (μm) | (10⁻⁸ mol/cm²) | (mA/cm²) | (V) | FF | (%) | (%) |
| Example 8 | 3 | 14.8 | 2.71 | 5.08 | 0.71 | 9.77 | 5 |
| Example 9 | 6 | 8.7 | 2.65 | 5.21 | 0.71 | 9.81 | 4 |
| (Example 1) | | | | | | | |
| Example 10 | 12 | 5.1 | 2.51 | 5.32 | 0.73 | 9.75 | 2 |
| Comparative | 0 | 22.0 | 2.75 | 4.87 | 0.6 | 8.04 | 10 |
| Example 3 | | | | | | | |
| Comparative | 1.5 | 19.2 | 2.73 | 4.89 | 0.68 | 9.08 | 11 |
| Example 4 | | | | | | | |
| Comparative | 15 | 0.9 | 2.51 | 5.37 | 0.67 | 9.03 | 15 |
| Example 5 | | | | | | | |
| Comparative | 20 | 0.5 | 2.26 | 5.35 | 0.67 | 8.10 | 24 |
| Example 6 | | | | | | | |

From the results shown in Table 2, the following was understood. That is, in a case where the film thickness of the porous insulating layer was set to be 3 to 12 μm, the adsorption amount of the metal complex dye could be set within a predetermined range, and accordingly, both the photoelectric conversion efficiency and the heat-resistant durability could be improved to a high level. In contrast, in a case where the film thickness of the porous insulating layer was set to be equal to or smaller than 1.5 μm, the adsorption amount of the metal complex dye was too large, and the battery characteristics (particularly open voltage) deteriorated. Meanwhile, in a case where the film thickness of the porous insulating layer was set to be equal to or greater than 15 μm, the adsorption amount of the metal complex dye was too small, and both the battery characteristics (particularly short-circuit current density) and the heat-resistant durability deteriorated.

Hitherto, the present invention and the embodiment thereof have been described. However, the inventors consider that, unless otherwise specified, the present invention is not limited to any of the details of the description of the present invention, and the present invention should be interpreted in a broad sense without departing from the gist and scope of the present invention shown in the attached claims.

The present application claims a priority based on JP2016-042561 filed on Mar. 4, 2016 in Japan, the content of which is incorporated herein by reference as a portion of the description of the present specification.

### EXPLANATION OF REFERENCES

1: supporting substrate
2: first conductive layer
3: scribe line
4: power generating layer
4a: porous semiconductor layer
4b: porous insulating layer
6: counter electrode (counter electrode conductive layer)
6a: catalyst layer
6b: second conductive layer
7: cover layer
8: sealing material
9: electrolyte filling region (electrolyte)
10: photoelectric conversion element
20: photoelectric conversion module

What is claimed is:

1. A photoelectric conversion element comprising:
a supporting substrate;
a conductive layer;
a power generating layer onto which a metal complex dye is adsorbed; and
a counter electrode,
wherein the conductive layer, the power generating layer, and the counter electrode are laminated in this order on the supporting substrate,
some or all of voids provided in each of the power generating layer and the counter electrode contain an electrolyte,
an adsorption amount of the metal complex dye is 1.0×10⁻⁸ to 1.8×10⁻⁷ mol/cm², and
the metal complex dye is represented by Formula (1), 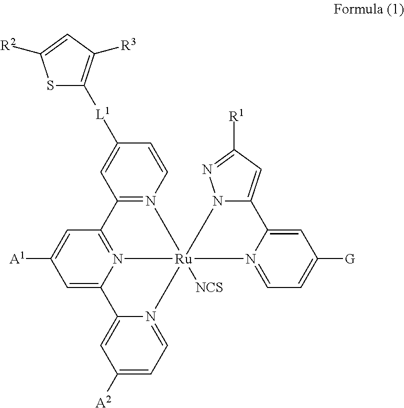
in Formula (1), G represents a group represented by any of Formulae (G-1) to (G-4), A¹ and A² each independently represent a carboxy group or a salt of a carboxy group, L¹ represents a group represented by any of Formulae (A-1) and (A-2), R¹ represents a hydrogen atom, an alkyl group, or an aryl group, R² represents a hydrogen atom or an alkyl group, and R³ represents an alkyl group, 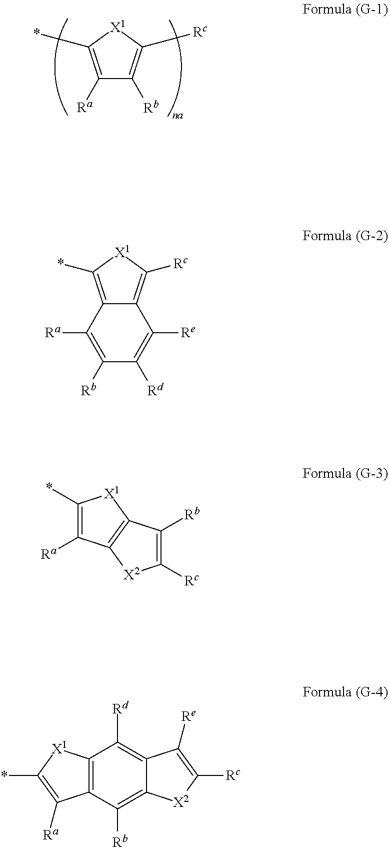
In Formulae (G-1) to (G-4), X¹ and X² each independently represent —O—, —S—, —Se—, —N(R^{A})—, —C(R^{A})₂—, or —Si(R^{A})₂—, R^{A} represents a hydrogen atom, an alkyl group, or an aryl group, na is an integer of 1 to 3, R^{a} represents an alkyl group, an alkoxy group, an alkylthio group, or an amino group, R^{b}, R^{c}, R^{d}, and R^{e} each independently represent a hydrogen atom or a substituent, and * represents a position bonded to a pyridyl group, 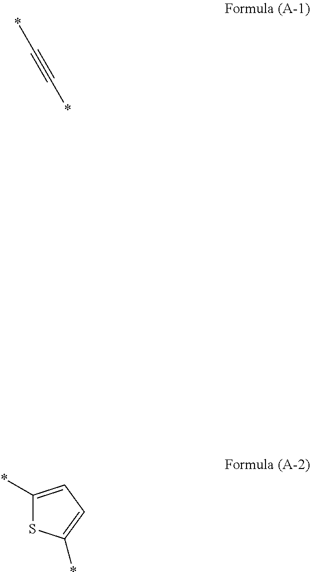
in each of Formulae (A-1) and (A-2), one of two *'s represents a position bonded to a thienyl group, and the other represents a position bonded to a pyridyl group.

2. The photoelectric conversion element according to claim 1,
wherein G is represented by Formula (G-1).

3. The photoelectric conversion element according to claim 1,
wherein the metal complex dye is represented by Formula (2), 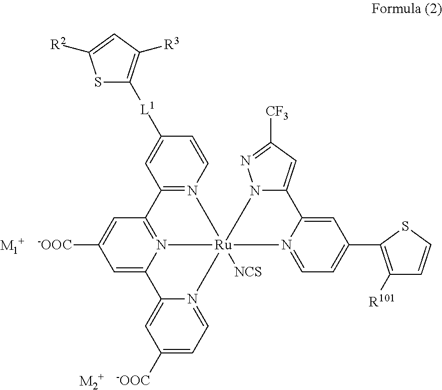
in Formula (2), M₁⁺ and M₂⁺ each independently represent a proton or a counterion, L¹ represents a group represented by any of Formulae (A-1) and (A-2), R¹⁰¹ represents an alkyl group, R² represents a hydrogen atom or an alkyl group, and R³ represents an alkyl group, 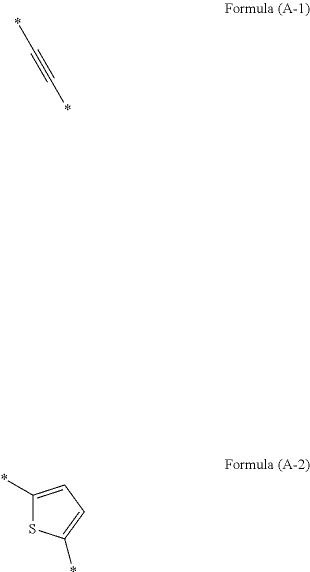
in each of Formulae (A-1) and (A-2), one of two *'s represents a position bonded to a thienyl group, and the other represents a position bonded to a pyridyl group.

4. The photoelectric conversion element according to claim 3,
wherein R¹⁰¹ represents an alkyl group having 2 to 12 carbon atoms.

5. The photoelectric conversion element according to claim 1,
wherein the power generating layer includes a porous semiconductor layer.

6. The photoelectric conversion element according to claim 1,
wherein the power generating layer includes a laminate of a porous semiconductor layer and a porous insulating layer.

7. The photoelectric conversion element according to claim 6,
wherein a film thickness of the porous insulating layer is 3 to 12 μm.

8. The photoelectric conversion element according to claim 6,
wherein the porous insulating layer is formed of at least one kind of insulating material selected from the group consisting of zirconium oxide, silicon oxide, aluminum oxide, magnesium oxide, and titanium oxide.

9. The photoelectric conversion element according to claim 8,
wherein an average particle size of the zirconium oxide, the silicon oxide, the aluminum oxide, and the magnesium oxide is 50 to 300 nm, and
an average particle size of the titanium oxide is 100 to 600 nm.

10. The photoelectric conversion element according to claim 5,
wherein the porous semiconductor layer is formed of a semiconductor material having an average particle size of 5 to 50 nm.

11. The photoelectric conversion element according to claim 1,
wherein the counter electrode includes a catalyst layer and a conductive layer.

12. The photoelectric conversion element according to claim 11,
wherein the conductive layer included in the counter electrode contains at least one kind of material among titanium, molybdenum, nickel, and carbon.

13. A photoelectric conversion module comprising:
a plurality of the photoelectric conversion elements according to claim 1 that are connected to each other.
